(19) United States
(12) Patent Application Publication
(10) Pub. No.: US 2025/0275025 A1
(43) Pub. Date: Aug. 28, 2025

(54) HEATING SYSTEMS AND HIGH-FREQUENCY POWER SUPPLIES APPLIED TO HEATING SYSTEMS

(71) Applicant: MEISHAN BOYA ADVANCED MATERIALS CO., LTD., Meishan (CN)

(72) Inventors: Yu WANG, Meishan (CN); Weiming GUAN, Meishan (CN); Min LI, Meishan (CN)

(73) Assignee: MEISHAN BOYA ADVANCED MATERIALS CO., LTD., Meishan (CN)

(21) Appl. No.: 19/208,546

(22) Filed: May 14, 2025

Related U.S. Application Data
(63) Continuation of application No. PCT/CN2022/136968, filed on Dec. 6, 2022.

(51) Int. Cl. H05B 6/80; H02M 3/335

(52) U.S. Cl. CPC H05B 6/80; H02M 3/335

(57) ABSTRACT

Embodiments of the present disclosure provide a heating system and a high-frequency power supply applied to the heating system. The heating system comprises a pot body configured to contain powder to be heated; a high-frequency power supply configured to supply an output signal with a power of not less than 5 kw and a frequency of not less than 1 MHz; and a resonant assembly configured to generate an electromagnetic field for directly heating the powder to be heated under driving of the output signal. The present disclosure provides a high-frequency signal to the resonant assembly through the high-frequency power supply, drives the resonant assembly to generate an electromagnetic field that directly acts on the powder, heats the powder while reducing the energy transmitted to the pot body, and avoids distortion or evaporation of the pot body due to heating, thereby realizing the heating of high-melting-point powder.

### CROSS-REFERENCE TO RELATED APPLICATIONS

The present application is a continuation of International Application No. PCT/CN2022/136968, filed on Dec. 6, 2022, the entire contents of which are hereby incorporated by reference.

### TECHNICAL FIELD

The present disclosure relates to heating technology, and in particular, to heating systems and high-frequency power supplies applied to heating systems.

### BACKGROUND

Heating technology is a critical component of modern industrial production. For example, in the field of crystal growth, the object to be heated is typically powder contained within a crucible. The heating system usually supplies energy via a power source to heat the crucible, which in turn transfers thermal energy to the powder inside, thereby achieving the heating and melting of the powder.

However, current heating systems often struggle to process certain powders with relatively high melting points. For example, when the melting point of the powder is close to the softening point of the crucible, heating the crucible to transfer heat for melting can easily cause deformation of the crucible. In severe cases, the material of the crucible may even volatilize and contaminate the powder.

### SUMMARY

One of the embodiments of the present disclosure provides a pot body configured to contain powder to be heated; a high-frequency power supply configured to supply an output signal with a power of not less than 5 kw and a frequency of not less than 1 MHz; and a resonant assembly configured to generate an electromagnetic field for directly heating the powder to be heated under driving of the output signal.

In some embodiments, the resonant assembly includes a first coil, the first coil is disposed at a bottom of the pot body, and the first coil generates the electromagnetic field under driving of the output signal.

In some embodiments, the resonant assembly includes a second coil, and the second coil is disposed around the pot body.

In some embodiments, a temperature field generated by the electromagnetic field for heating the powder to be heated includes a first temperature and a second temperature, the first temperature is a temperature at a position affixed to the pot body, and the second temperature is a temperature at a preset distance from the pot body, the first temperature being less than the second temperature.

In some embodiments, the powder to be heated includes one or more of lutetium yttrium oxyorthosilicate (LYSO), gallium aluminum garnet, yttrium aluminum garnet, aluminum oxide crystal, lithium tantalate crystal, lithium niobate crystal, barium borate crystal, lithium triborate crystal, or a doped crystal including one or more elements from metal elements or transition elements.

In some embodiments, the high-frequency power supply includes a direct current (DC) voltage regulator, a power device, and a transformer; the DC voltage regulator is configured to receive a signal to be regulated and output a target regulated signal to the power device, the power device is configured to adjust a power of the target regulated signal to produce an electrical signal at a target alternating current (AC) frequency, and the transformer is configured to adjust a voltage of the electrical signal at the target AC frequency to enable the high-frequency power supply to provide the output signal.

In some embodiments, the DC voltage regulator includes a plurality of DC voltage regulator modules connected in parallel, an input terminal of each of the plurality of DC voltage regulator modules receives the signal to be regulated, respectively, and there is a time delay between the signals to be regulated received by different DC voltage regulator modules, and an output terminal of the plurality of DC voltage regulator modules connected in parallel outputs the target regulated signal, the target regulated signal is a superposition of regulated signals output by each of the plurality of DC voltage regulator modules.

In some embodiments, the DC voltage regulator module includes a Buck circuit and an LLC circuit, an input terminal of the Buck circuit receives the signal to be regulated, an output terminal of the Buck circuit is connected to an input terminal of the LLC circuit, and an output terminal of the LLC circuit outputs a signal that has been regulated by the Buck circuit and the LLC circuit.

In some embodiments, the power device includes: multi-level power modules, and a power module at each level is configured to generate an electrical signal at a preset AC frequency; a controller configured to control an operation state of one or more of power modules among the multi-level power modules; and an output terminal, coupled to the power module at each level among the multi-level power modules, respectively, and configured to generate an electrical signal at the target AC frequency according to an operation state of the multi-level power modules, and there is a corresponding relationship between the target AC frequency and a preset AC frequency of the power module at each level.

In some embodiments, a power of an electrical signal generated at the output terminal is the same as a sum of powers output by the multi-level power modules.

In some embodiments, the controller controls the multi-level power modules to be in operation states during different periods, respectively, and a sum of the preset AC frequency of the power module at each level is the same as the target AC frequency.

In some embodiments, the transformer a multi-layer printed circuit board (PCB), wherein each layer of the PCB includes a hollow structure; a multi-layer planar coil, wherein each layer of the planar coil is fixed to one layer of the PCB and disposed around the hollow structure; and a magnetic core structure, wherein the magnetic core structure includes a plurality of magnetic core plates, each of the plurality of magnetic core plates is disposed within the hollow structure of one layer of the PCB, and there is a spacing between two adjacent magnetic core plates.

In some embodiments, a thickness of each layer of the PCB is not more than 0.4 mm and a thickness of each layer of the planar coil is not more than 17 μm.

In some embodiments, the PCB is provided with one or more pads, and each of the one or more pads is configured to separate two adjacent layers of the PCB.

In some embodiments, the high-frequency power supply further includes a rectifier circuit, the rectifier circuit is connected to the DC voltage regulator, and the rectifier circuit is configured to rectify an external power supply and output a signal to be regulated.

One of the embodiments of the present disclosure provides a direct current (DC) voltage regulator applied to a high-frequency power supply. The DC voltage regulator comprises a plurality of DC voltage regulator modules connected in parallel, an input terminal of each of the plurality of DC voltage regulator modules receives a signal to be regulated, respectively, and there is a time delay between the signals to be regulated received by different DC voltage regulator modules, and an output terminal of the plurality of DC voltage regulator modules connected in parallel outputs a target regulated signal, and the target regulated signal is a superposition of regulated signals output by each of the plurality of DC voltage regulator modules.

In some embodiments, each of the plurality of DC voltage regulator modules includes a first regulator circuit and a second regulator circuit, the first regulator circuit and the second regulator circuit are connected in series, and the first regulator circuit and the second voltage regulator circuit have different efficiencies.

In some embodiments, the first voltage regulator circuit is a Buck circuit, the second voltage regulator circuit is an LLC circuit, an input terminal of the Buck circuit receives the signal to be regulated, and an output terminal of the Buck circuit is connected to an input terminal of the LLC circuit, and an output terminal of the LLC circuit outputs a signal that has been regulated by the Buck circuit and the LLC circuit.

In some embodiments, a time delay between signals to be regulated received by two adjacent DC voltage regulator modules is related to a signal at an output terminal of at least one DC voltage regulator module

In some embodiments, a ratio of a period of a signal at the output terminal of the DC voltage regulator module to a count of the plurality of DC voltage regulator modules is correlated with the time delay.

In some embodiments, a magnitude of the time delay is the same as the ratio of the period of the signal at the output terminal of the DC voltage regulator module to the count of the plurality of DC voltage regulator modules.

In some embodiments, the input terminals of the plurality of the DC voltage regulator modules are connected to a rectifier circuit, the rectifier circuit is configured to rectify an external power supply and provide the signals to be regulated to the plurality of DC voltage regulator modules connected in parallel; and the output terminal of the plurality of DC voltage regulator modules is connected to a power device and configured to provide the target regulated signal to the power device to enable the power device to generate an electrical signal at a target AC frequency.

One of the embodiments of the present disclosure provides a power device applied to a high-frequency power supply. The power device comprises multi-level power modules, and a power module at each level is configured to generate an electrical signal at a preset AC frequency; a controller configured to control an operation state of one or more of power modules among the multi-level power modules; and an output terminal, coupled to the power module at each level among the multi-level power modules, respectively, and configured to generate an electrical signal at the target AC frequency according to an operation state of the multi-level power modules, and there is a corresponding relationship between the target AC frequency and a preset AC frequency of the power module at each level.

In some embodiments, a power of an electrical signal generated at the output terminal is the same as a sum of powers output by the multi-level power modules.

In some embodiments, the controller controls a plurality of stages of power modules to be in separate states of operation for different time periods, with the sum of the preset AC frequencies of each stage of the power modules being the same as a target AC frequency.

In some embodiments, electrical signals generated by the power module at each level have the same AC frequency.

In some embodiments, at least two electrical signals generated by the multi-level power modules have different AC frequencies.

In some embodiments, the preset AC frequency of the power module at each level is not less than 1 MHz and the target AC frequency is not less than 4 MHz.

In some embodiments, the power module at each level is a gallium nitride module.

In some embodiments, wherein the gallium nitride module at each level includes four gallium nitride transistors, a capacitor, an inductor, and a resistor, every two gallium nitride transistors constitute an output loop, and the capacitor is connected in parallel with the two gallium nitride transistors, the inductor and the resistor are disposed on the output loop, and the output loop is configured to generate the electrical signal at the preset AC frequency.

In some embodiments, the power device is further configured to adjust the target AC frequency of the electrical signal when a ratio of a reactive power of the high-frequency power supply to an output power of the high-frequency power supply exceeds a preset threshold value.

In some embodiments, the multi-level power modules are connected to a plurality of DC voltage regulator modules, and the plurality of DC voltage regulator modules are configured to provide a target regulated signal to the multi-level power modules; and the output terminal is connected to a transformer, and the output terminal provides the electrical signal at the target AC frequency to the transformer to enable the transformer to transform the electrical signal at the target AC frequency to generate an output signal.

One of the embodiments of the present disclosure provides a transformer applied to a high-frequency power supply. The transformer comprises a multi-layer PCB, wherein each layer of the PCB includes a hollow structure; a multi-layer planar coil, wherein each layer of the planar coil is fixed to one layer of the PCB and disposed around the hollow structure; and a magnetic core structure, wherein the magnetic core structure includes a plurality of magnetic core plates, each of the plurality of magnetic core plates is disposed within the hollow structure of one layer of the PCB, and there is a spacing between two adjacent magnetic core plates.

In some embodiments, a thickness of each layer of the PCB is not more than 0.4 mm and a thickness of each layer of the planar coil is not more than 17 μm.

In some embodiments, the PCB is provided with one or more pads, and each of the one or more pads is configured to separate two adjacent layers of the PCB.

In some embodiments, there is an inverse relationship between a cross-sectional area of each of the plurality of magnetic core plates and a count of turns of the multi-layer planar coil.

In some embodiments, there is a proportional relationship between a spacing between cables of the multi-layer planar coil and a maximum operation voltage of the transformer, and there are proportional relationships between a radial dimension and a maximum operation current of the transformer and a thickness of the multi-layer planar coil and the maximum operation current of the transformer, respectively.

In some embodiments, an operation frequency of the transformer is in a range of 700 kHz to 4 MHz, and a ratio of a cross-sectional area of a cable of the multi-layer planar coil to a winding area of the multi-layer planar coil is in a range of 80% to 90%.

In some embodiments, a material of the magnetic core structure is PC200 ferrite.

In some embodiments, at least two layers of the planar coil in the multi-layer planar coil proximate to a primary side of the transformer are connected in series and at least two layers of the planar coil in the multi-layer planar coil proximate to a secondary side of the transformer are connected in parallel, the primary side of the transformer is configured to receive an electrical signal at a target AC frequency from a power device, and the secondary side of the transformer is configured to generate an output signal.

The present disclosure provides a high-frequency signal to the resonant assembly through the high-frequency power supply, drives the resonant assembly to generate an electromagnetic field that directly acts on the powder, heats the powder while reducing the energy transmitted to the pot body, and avoids distortion or evaporation of the pot body due to heating, thereby realizing the heating of high-melting-point powder.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, wherein:

FIG. 1 is a block diagram of a structure of a heating system according to some embodiments of the present disclosure;

FIG. 2 is a schematic diagram illustrating an exemplary cross-sectional structure of a heating device according to some embodiments of the present disclosure;

FIG. 3 is a schematic diagram illustrating an exemplary structure of a resonant assembly according to some embodiments of the present disclosure;

FIG. 4 is a schematic diagram illustrating a temperature field effect of a heating device according to some embodiments of the present disclosure;

FIG. 5 is a block diagram of a structure of a high-frequency power supply according to some embodiments of the present disclosure;

FIG. 6 is a block diagram of a structure of a direct current (DC) voltage regulator according to some embodiments of the present disclosure;

FIG. 7 is a schematic diagram illustrating a signal regulator principle according to some embodiments of the present disclosure;

FIG. 8 is a schematic diagram illustrating a circuit of a DC voltage regulator module according to some embodiments of the present disclosure;

FIG. 9 is a block diagram of a structure of a power device according to some embodiments of the present disclosure;

FIG. 10 is a schematic diagram illustrating a circuit of a power device according to some embodiments of the present disclosure;

FIG. 11 is a schematic diagram illustrating the integration of signals according to some embodiments of the present disclosure;

FIG. 12 is a schematic diagram illustrating a circuit structure of a driver module according to some embodiments of the present disclosure;

FIG. 13 is a block diagram of a structure of a transformer shown according to some embodiments of the present disclosure;

FIG. 14A is a schematic diagram illustrating a three-dimensional structure of a transformer according to some embodiments of the present disclosure;

FIG. 14B is a schematic diagram illustrating a perspective view of a transformer according to some embodiments of the present disclosure;

FIG. 14C is a schematic diagram illustrating a cross-sectional structure of a transformer according to some embodiments of the present disclosure;

FIG. 14D is a schematic diagram illustrating a cross-sectional structure of one layer of a PCB according to some embodiments of the present disclosure;

FIG. 15A is a schematic diagram illustrating a simplified structure of a transformer according to some embodiments of the present disclosure;

FIG. 15B is a schematic diagram illustrating a simplified perspective view of a transformer according to some embodiments of the present disclosure;

FIG. 16A is a schematic diagram illustrating a temperature field effect of an existing transformer; and

FIG. 16B is a schematic diagram illustrating a temperature field of a transformer shown according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” and/or “module” as used herein are a way to distinguish between different levels of components, parts, sections, or assemblies. However, the words may be replaced by other expressions if other words accomplish the same purpose.

As shown in the present disclosure and in the claims, unless the context clearly suggests an exception, the words “a”, “an”, “one” and/or “the” do not refer specifically to the singular but may also include the plural. Generally, the term “comprising” suggests only the inclusion of clearly identified steps and elements that do not constitute an exclusive list. These steps and elements do not constitute an exclusive list, and the method or device may also contain other steps or elements.

Flowcharts are used in the present disclosure to illustrate operations performed by a system in accordance with embodiments of the present disclosure. It should be appreciated that the preceding or following operations are not necessarily performed in an exact sequence. Instead, steps can be processed in reverse order or simultaneously. Also, it is possible to add other operations to these processes or remove a step or steps from these processes.

In some embodiments, a heating system is capable of providing high temperatures, making it suitable for a variety of high-temperature applications. These include production scenarios such as evaporation, concentration, or crystallization of solutions; industrial design processes involving repeated heating and molding; and smelting scenarios such as the extraction of ores and metals.

In some embodiments, the heating system can be applied to crystal growth. The heating system may include a power source that supplies electrical energy, which is converted and transferred as thermal energy to heat the powder. This causes the powder to reach its melting point and form a melt, which becomes supersaturated at the seed crystal region, thereby enabling the growth of the seed crystal and the formation of a crystal.

The present disclosure provides a high-frequency signal to a resonant assembly through a high-frequency power supply, drives the resonant assembly to generate an electromagnetic field that directly acts on powder, heats the powder while reducing the energy transmitted to the pot body, and avoids distortion or evaporation of the pot body due to heating, thereby realizing the heating of high-melting-point powder.

It should be understood that the application scenarios of the heating system of the present disclosure are only some examples or embodiments of the present disclosure, and that a person of ordinary skill in the art may, without creative labor, apply the present disclosure to other similar scenarios in accordance with the accompanying drawings.

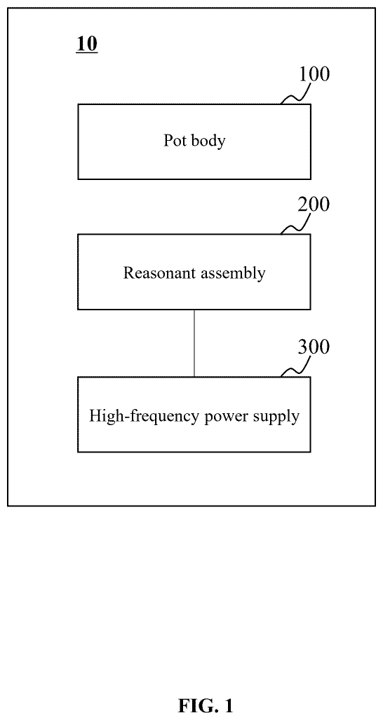

The heating system to which the embodiments of the present disclosure relate is described in detail below in conjunction with FIG. 1 to FIG. 15B and FIG. 16B. The following embodiments of the present disclosure are described in detail. It should be noted that the following embodiments are used only to explain the present disclosure and do not constitute a limitation of the present specification.

FIG. 1 is a schematic diagram illustrating modules of a heating system according to some embodiments of the present disclosure. In some embodiments, the heating system may include a heating device and a high-frequency power supply. The high-frequency power supply is configured to provide electrical energy to the heating device to enable the heating device to generate a high temperature. The heating device may include a pot body and a resonant assembly. As shown in FIG. 1, in some embodiments, the heating system 10 includes a pot body 100, a resonant assembly 200, and a high-frequency power supply 300. The pot body 100 is configured to contain powder to be heated, the high-frequency power supply 300 is configured to provide an output signal with a power and/or a frequency satisfying certain conditions, and the resonant assembly 200 is configured to generate an electromagnetic field for directly heating the powder to be heated under driving of the output signal. In some embodiments, to cause sufficient oscillation and friction of the electrons outside the atomic nucleus in the powder under the influence of an electromagnetic field, the high-frequency power supply 300 is required to provide an output signal with a power of no less than 5 kW and a frequency of no less than 1 MHz.

The pot body 100 may be a vessel with an accommodation space for containing the powder to be heated. In some embodiments, the material of the pot body 100 may include chemically stable materials such as iridium, platinum, tungsten, molybdenum, ceramics, alumina, zirconia, copper, and stainless steel to prevent contamination of the powder to be heated. In some embodiments, in addition to containing the powder to be heated, the pot body 100 may also be configured to contain insulating powder to separate the powder to be heated and the pot body 100, preventing contamination of the powder to be heated by substances evaporating from the pot body 100 during heating. In some embodiments, when the powder to be heated is melted, the insulating powder may remain solid to hold melted powder to be heated. Since the heating device directly heats the powder to be heated through an electromagnetic field, a plurality of different temperatures may exist within the pot body 100. For example, the temperature near the pot body 100 may be lower than that at a location farther from the pot body 100. During the heating process, the insulating powder is closer to the pot body 100 than the powder to be heated, such that the temperature of the insulating powder may be lower than the temperature of the powder to be heated, and unmelted insulating powder may be used to hold the powder to be heated when the powder to be heated is melted and may also be used to separate the powder to be heated from the pot body 100, preventing contamination of the powder to be heated by substances evaporating from the pot body 100 during heating.

In some embodiments, the insulating powder and the powder to be heated may be of the same material. That is, a portion of the powder near the pot body 100 (i.e., the insulating powder) does not melt, allowing it to support the portion of the powder farther from the pot body 100 (i.e., the powder to be heated). In some embodiments, the insulating powder and the powder to be heated may be made of different materials, and the insulating powder may have a melting point that is higher than, or close to, that of the powder to be heated. In this way, after the powder to be heated has reached its melting point and melted, the insulating powder is still solid and can support the melted powder to be heated.

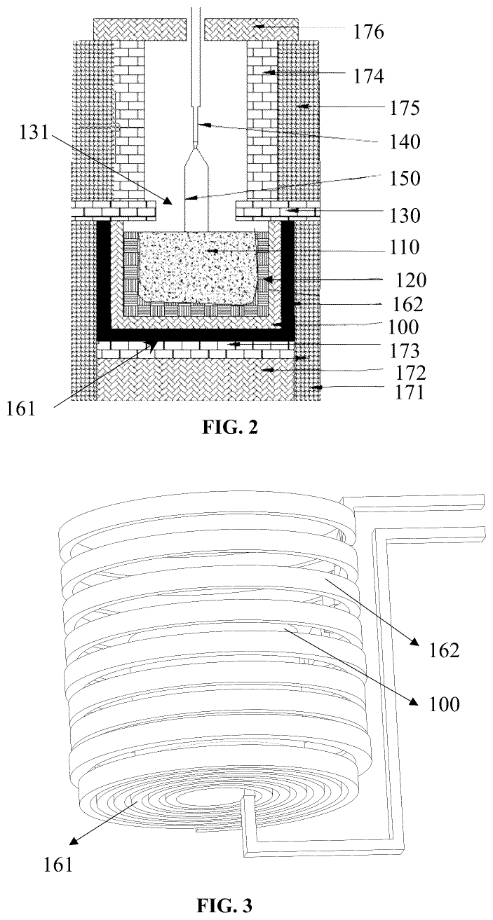

FIG. 2 is a schematic diagram illustrating an exemplary cross-section of a heating device according to some embodiments of the present disclosure. As shown in FIG. 2, the pot body 100 is arranged in a cavity of the heating device, and the pot body 100 contains powder to be heated 110. In some embodiments, the pot body 100 may also contain insulating powder 120, and the insulating powder 120 may be affixed to an inner wall and the bottom wall of the pot body 100, and the insulating powder 120 may be used to support the powder to be heated 110. In some embodiments, the heating device may further include a lid 130, the lid may cover the pot body 100, and a peripheral wall of the lid 130 may be connected to an outer shell of the heating device to avoid evaporation of the powder to be heated 110. In some embodiments, the lid 130 may be provided with a channel 131, and the channel 131 may be used to fill material into the pot body 100, and reach and stir the material in the pot body 100.

In some embodiments, the heating system 10 may be applied in the field of crystal growth, and the material of the powder to be heated 110 may include crystal powder. Further, in some embodiments, the powder to be heated 110 may include one or more of lutetium yttrium oxyorthosilicate (LYSO), gallium aluminum garnet, yttrium aluminum garnet, aluminum oxide crystal, lithium tantalate crystal, lithium niobate crystal, barium borate crystal, lithium triborate crystal, or a doped crystal including one or more elements from metal elements or transition elements, to obtain corresponding crystals through crystal growth. Taking FIG. 2 as an example, the heating device may utilize the electromagnetic field to heat the powder to be heated 110, and when the powder to be heated 110 melts, a lifting bar fixed with seed crystals 140 at the tip may be lowered in the channel 131 to insert the seed crystals 140 into a melt of the powder to be heated 110, and then the temperature may be adjusted to grow the seed crystals 140. Then, the lifting bar is slowly raised, causing crystals 150 to grow on one side while being gradually pulled out.

The high-frequency power supply 300 may be a power supply device that outputs a high-frequency electrical signal. In some embodiments, the high-frequency power supply 300 may provide an output signal with a power and/or frequency that satisfies certain conditions. The output signal may be an alternating current (AC) and may be used to drive the resonant assembly 200 to resonate to generate an alternating electromagnetic field. Correspondingly, in the alternating electromagnetic field, the orientation of the powder molecules can change with the variations in the electromagnetic field, causing the electrons outside the atomic nuclei to move irregularly. The oscillation and friction between the electrons generate heat, thereby heating the powder. Due to the varying distribution of the electromagnetic field strength in space, the polarization effect on molecules at different positions is of varying intensity, leading to differences in the intensity of electron movement. As a result, the amount of heat generated at different positions within the heating device also varies. In some embodiments, the powder to be heated 110 can be placed in a position where the electromagnetic field strength is stronger, while the pot body 100 can be placed in a position where the electromagnetic field strength is weaker, which allows the temperature of the powder to be heated 110 to be higher than that of the pot body 100 during the heating process.

In some embodiments of the present disclosure, the high-frequency signal may be provided to the resonant assembly 200 by the high-frequency power supply 300, driving the resonant assembly 200 to generate the electromagnetic field, and by placing the pot body 100 in a position with a weaker electromagnetic field strength, and the powder to be heated 110 in a position with a stronger electromagnetic field strength, the intensity of the electron movement in the powder to be heated 110 is greater than the intensity of the electron movement in the pot body 100, causing the temperature of the powder to be heated 110 to be higher than the temperature of the pot body 100. As a result, the heating system 10 can heat the powder while reducing the energy transmitted to the pot body, preventing deformation or volatilization of the pot body due to heating and enabling the heating of high-melting-point powders.

In some embodiments, there is a correspondence between the power and/or frequency of the output signal and thermal energy provided to the powder by the heating system 10. The power of the output signal can affect the intensity of the electron movement, oscillation, and friction in the alternating magnetic field, while the frequency of the output signal can influence the number of oscillations and friction occurrences of electron movement in the alternating magnetic field. For example, the greater the power of the output signal, the greater the strength of the alternating electromagnetic field generated by the resonant assembly 200, which results in the greater strength of the oscillation and friction of the electrons, and the greater the thermal energy generated by the heating system 10. As another example, the higher the frequency of the output signal, the higher the frequency of the alternating electromagnetic field generated by the resonant assembly 200, which results in the greater number of oscillations and frictions of the electrons per unit time, and the greater the thermal energy generated by the heating system 10.

In some embodiments, the frequency of the output signal may be determined based on the melting point of the powder to be heated. In some embodiments, the powder to be heated may include crystal powder, and a correspondence between the melting point of the crystalline powder and the frequency of the output signal may be represented by the following formula:

$$F = \frac{3 \times 1 {0}^{6} p}{{D}^{2}}$$

where, F denotes the minimum frequency of the output signal, p denotes the resistivity of the crystal powder at the melting point, and D2 denotes the diameter of the pot body 100. That is, the higher the melting point of the powder to be heated, the higher the frequency required for the output signal when the size of the pot body 100 is constant.

In some embodiments, the frequency of the output signal may be determined based on the amount of the powder to be heated. For example, the greater the amount of the powder to be heated during the same heating duration, the more thermal energy that needs to be supplied to the powder by the heating system 10, and the higher the power required for the output signal.

In order to cause sufficient oscillation and friction of electrons outside the nuclei of the atoms in the powder under the action of the electromagnetic field, sufficient thermal energy that can be generated by the heating system 10, in some embodiments, the high-frequency power supply 300 can be supplied with an output signal having a power of no less than 5 kw and a frequency of no less than 1 MHz output signal.

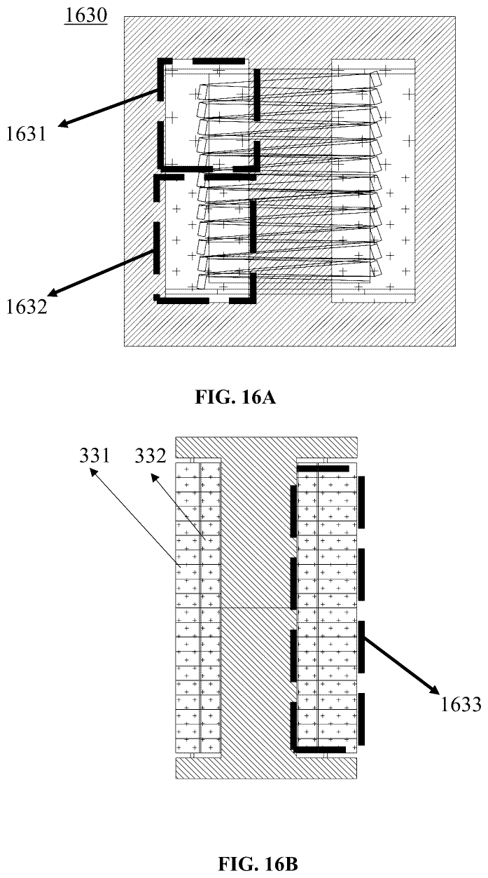

In some embodiments, the high-frequency power supply 300 may include a rectifier device and a power device. The rectifier device may be configured to rectify a received three-phase electrical signal to produce a direct current (DC) signal, and the power device may be configured to convert the direct current signal to the alternating current (AC) signal and adjust the power of the AC signal accordingly. In some embodiments, the high-frequency power supply 300 may further include a direct current (DC) voltage regulator, and the DC voltage regulator may be disposed between the rectifier device and the power device and is configured to stabilize the voltage of a DC electrical signal. In some embodiments, the high-frequency power supply 300 may further include a transformer, and the transformer may be configured to transform an AC electric signal output from the power device, so that the high-frequency power supply 300 can provide an output signal whose power and frequency satisfy certain conditions. The specific realization of the high-frequency power supply 300 can be found in other contents of the present disclosure, for example, FIG. 5 to FIG. 15B, FIG. 16B, and the related descriptions thereof.

The resonant assembly 200 may generate an alternating electromagnetic field under the driving of the output signal (i.e., the AC signal) of the high-frequency power supply 300. The electromagnetic field may drive the electrons outside the nuclei of the atoms in the powder to move, thereby heating the powder. In some embodiments, the strength of the electromagnetic field is related to the power and/or frequency of the output signal. Taking the frequency as an example, the higher the frequency of the output signal, the higher the frequency of the alternating electromagnetic field that results in the faster movement of the electrons in the powder, and the more intense the oscillation and friction between the electrons, and thus the thermal energy generated by the heating system 10 is the more.

In some embodiments, the resonant assembly 200 may include one or more metal members. The metal members may generate the alternating electromagnetic field through the phenomenon of magnetic induction when the AC electrical signal passes through the metal members. The electromagnetic fields generated by a plurality of metal members may interact with each other, thereby causing a magnetic field vortex to be generated within the resonant assembly 200, which accelerates the movement of electrons in the powder located at the location of the magnetic field vortex. In some embodiments, the metal members may include metal coils.

In some embodiments, the resonant assembly 200 may include a first coil. The first coil may be disposed at the bottom of the pot body, and the first coil may generate an electromagnetic field for heating the powder to be heated driven by the output signal.

FIG. 3 is a schematic diagram of a structure of a resonant assembly 200 shown according to some embodiments of the present specification.

As shown in FIG. 2 and FIG. 3, a first coil 161 may be disposed at the bottom of the pot body 100. After receiving an output signal, the first coil 161 may generate an electromagnetic field, and the electromagnetic field may act on the powder to be heated 110 after passing through the pot body 100 and the insulating powder 120, causing the orientation of the polar molecules in the powder to be heated 110 to change with the variations in the electromagnetic field, leading to friction between the electrons of adjacent molecules and thereby converting electromagnetic energy into thermal energy.

The field strength of the electromagnetic field may be elevated through increasing the power of the output signal to enhance the polarization of the polar molecules, which enhances the thermal movement of the electrons and the friction between adjacent electrons, and elevates the thermal energy generated by the heating system 10. The rate of change in polarity of the electromagnetic field (i.e., the frequency of the electromagnetic field) may also be elevated through elevating the frequency of the output signal to accelerate the polarization of polar molecules, thereby accelerating the thermal movement of electrons and friction between adjacent electrons, and elevating the amount of thermal energy generated by the heating system 10.

In some embodiments, the first coil 161 may be spaced a distance from the bottom of the pot body 100. The field strength of an electromagnetic field generated by the first coil 161 is uniformly distributed in a portion of the space, with a gradient distribution in another portion of the space. In some embodiments, the spatial position of the pot body 100 and/or the powder to be heated 110 in the electromagnetic field may be adjusted by adjusting the distance between the first coil 161 and the bottom of the pot body 100, thereby adjusting the field strength distribution of the electromagnetic field acting on the pot body 100 and/or the powder to be heated 110, henceforth realizing the adjustment of the temperature distribution. For example, when the field strength is distributed in a gradient, and the field strength in the space where the pot body 100 is located is less than the field strength in the space where the powder to be heated 110 is located, the movement intensity of the electrons of the pot body 100 is less than the movement intensity of the electrons of the powder to be heated 110, which results in the temperature of the powder to be heated 110 in the heating device being greater than the temperature of the pot body 100. In addition, if the field strength in the space where the powder to be heated 110 is located is uniformly distributed, and the movement intensity of the electrons of the powder to be heated 110 is uniform, then uniform heating of the powder to be heated 110 can be realized. For example, in some embodiments, the distance between the first coil and the bottom of the pot body 100 may be in a range of 40 mm to 80 mm.

In some embodiments, the resonant assembly 200 may include a second coil 162, and the second coil 162 is disposed around the pot body 100. In some embodiments, the second coil 162 may generate an electromagnetic field driven by the same or a different output signal as the first coil 161. Further, in some embodiments, the second coil 162 may cooperate with the first coil to generate a magnetic field vortex to elevate the thermal energy output from the heating system 10. Since the second coil 162 is at a different position in space from the first coil 161, an electromagnetic field generated by the first coil 161 and an electromagnetic field generated by the second coil 162 are distributed differently in space, such that the two electromagnetic fields may interact with each other to produce a magnetic field vortex.

As shown in FIG. 2 and FIG. 3, the second coil 162 may be disposed around the pot body 100, and one end of the second coil 162 may be in contact with or connected to the first coil 161. The second coil 162 may cooperate with the first coil 161 to form a cavity, and the electromagnetic field generated by the second coil 162 may affect the electromagnetic field generated by the first coil 161, thereby forming the magnetic field vortex. The magnetic field vortex causes electrons of the powder to be heated 110 in the magnetic field vortex to move faster and increase the friction between the electrons, thereby enhancing the thermal energy output of the heating system 10.

In some embodiments, a temperature field generated by the electromagnetic field for heating the powder to be heated 110 may include a first temperature and a second temperature. The first temperature refers to a temperature at a position affixed to the pot body 100, the second temperature refers to a temperature at a position in the pot body 100 with a preset distance from the pot body 100, and then the first temperature is less than the second temperature. In some embodiments, the position with a preset distance from the pot body 100 may include the position of the powder to be heated 110 and/or the position of the insulating powder 120. Since temperature is influenced by the strength of the electromagnetic field, the field strength at the position where the electromagnetic field is in contact with the pot body 100 can be lower than the field strength at the position with a preset distance from the pot body 100. As a result, the intensity of electron movement in the pot body 100 is lower than that at the preset distance. Under the effect of the electromagnetic field, the thermal energy generated in the pot body 100 is less than that generated at the preset distance, causing the first temperature to be less than the second temperature.

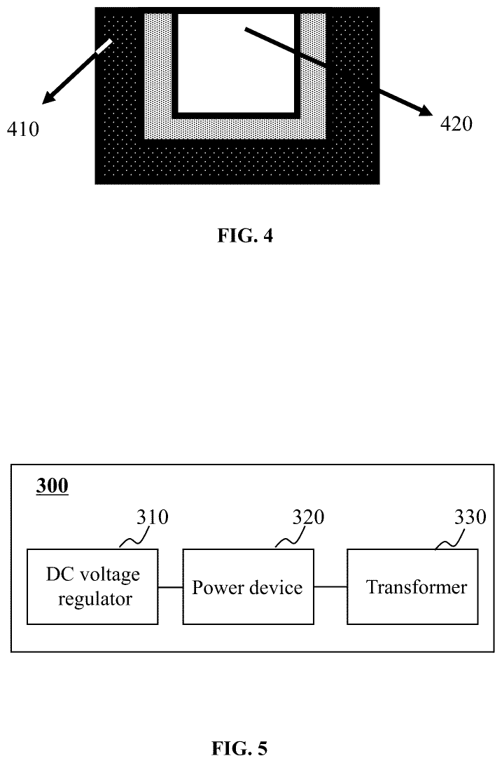

FIG. 4 is a schematic diagram illustrating a temperature field effect of a heating device according to some embodiments of the present disclosure. As shown in FIG. 4, a first temperature 410 may be a temperature at a position where the pot body 100 is located, and a second temperature 420 may be a temperature at a position with a preset distance from the pot body 100, i.e., the second temperature 420 may be a temperature of a portion of the powder to be heated 110 contained in the pot body 100. In the temperature field of the heating device, the first temperature 410 (as shown in FIG. 4, 410 corresponds to a darker temperature color) is less than the second temperature 420 (as shown in FIG. 4, 420 corresponds to a lighter temperature color). Another portion of the powder to be heated 110 or other insulating powder may be contained between the position corresponding to the first temperature 410 and the position corresponding to the second temperature 420.

A traditional heating device heats the pot body and then transfers the heat to the powder to be heated, resulting in the temperature at a position affixed to the pot body usually being higher compared to other positions. In embodiments of the present disclosure, the powder is heated by an electromagnetic field acting directly on the powder, resulting in the temperature at the pot body being lower than at other locations in the temperature field of the heating device, which helps prevent the pot body from deforming or volatilizing due to heating, thereby enabling the heating of high-melting-point powders.

Continuing with reference to FIG. 2, in some embodiments, the heating device may further include a first insulating enclosure 171 disposed around the first coil 161 and the second coil 162. The first insulating enclosure 171 is configured to insulate a cavity inside the first insulating enclosure 171 from the external environment, stabilizing the temperature of the components within the cavity. In some embodiments, the first insulating enclosure 171 may further be configured to support the lid 130. In some embodiments, the heating device may further include a lower pad 172, and the lower pad 172 may be provided at the bottom of the first coil 161 to support the first coil 161. In some embodiments, the heating device may further include a pot support 173 disposed between the first coil 161 and the pot body 100, and the pot support 173 is configured to support the pot body 100. The distance between the pot body 100 and the first coil 161 may be adjusted by controlling the position of the pot support 173.

In some embodiments, the heating device may further include an upper insulating inner cylinder 174, an upper insulating outer cylinder 175, and an upper cover plate 176. The upper insulating inner cylinder 174 and the upper insulating outer cylinder 175 may be disposed around the channel 131 of the lid 130, the upper cover plate 176 may be provided at the top of the upper insulating inner cylinder 174 and the upper insulating outer cylinder 175, and the surface of the upper cover plate 176 may be provided with through holes for filling material into the pot body 100, and seizing and stirring materials in the pot body 100. The upper insulating inner cylinder 174, the upper insulating outer cylinder 175, and the upper cover plate 176 may be used to separate the channel 131 from the external environment. In some embodiments, when the heating system 10 is applied in the field of crystal growth, the upper insulating inner cylinder 174, the upper insulating outer cylinder 175, and the upper cover plate 176 may be used to stabilize the seed crystal 140 during the heating process and the temperature of the crystal 150.

In the embodiment of the present disclosure, a high-frequency signal is supplied to the resonant assembly 200 through the high-frequency power supply 300, and the resonant assembly 200 is driven to generate an electromagnetic field to act directly on the powder, such a design can reduce the energy transmitted to the pot body 100 while heating the powder and prevent the pot body 100 from deforming or volatilizing due to heating, thereby enabling the heating of high-melting-point powders.

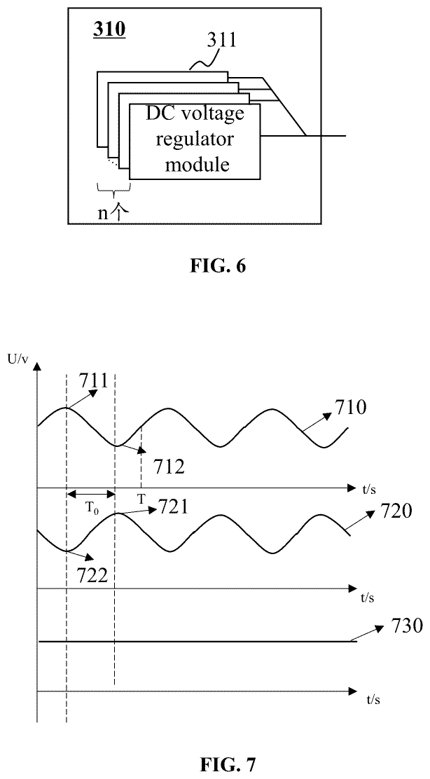

FIG. 5 is a schematic diagram illustrating modules of a high-frequency power supply 300 according to some embodiments of the present disclosure. As shown in FIG. 5, in some embodiments, the high-frequency power supply 300 includes a direct current (DC) voltage regulator 310, a power device 320, and a transformer 330. The DC voltage regulator 310 is configured to receive a signal to be regulated and output a target regulated signal to the power device 320. In some embodiments, the DC voltage regulator 310 may delay the reception of a plurality of signals to be regulated, and then offset the ripple of the signals to be regulated through superimposing the signals, thereby stabilizing the voltage of the target regulated signal obtained. The specific realization of the DC voltage regulator 310 can be referred to other contents in the present disclosure, such as FIG. 6 to FIG. 8, and the related descriptions thereof.

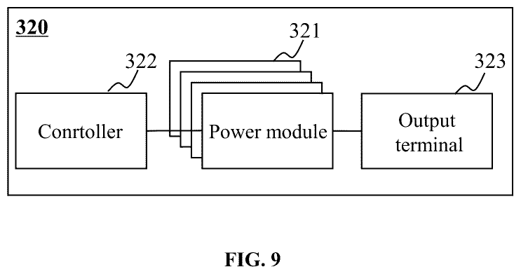

The power device 320 may generate an electrical signal at a target alternating current (AC) frequency by adjusting the power of the target regulated signal. In some embodiments, the power device 320 may generate electrical signals individually through multi-level power modules connected in parallel, and then the signals are merged by an output terminal of the multi-level power modules connected in parallel to generate the electrical signal at the target AC frequency. In some embodiments, the power at an output terminal of the power device 320 may be the same as the sum of the powers output by the power modules at multiple levels. In some embodiments, the multi-level power modules operate in a time-shared manner, and a sum of the preset AC frequencies of electrical signals output by each level of power modules is the same as the target AC frequency. In some embodiments, the multi-level power module operates at the same time, and the target AC frequency of the electrical signals output at the outputs may be the same as the preset AC frequency of the electrical signals output from each level of power modules. The specific realization of the power device 320 can be found elsewhere in the present disclosure, for example, in FIG. 9 to FIG. 12 and the related descriptions thereof.

The transformer 330 may transform the electrical signal at the target AC frequency to enable the high-frequency power supply 300 to provide an output signal. In some embodiments, the transformer 330 may perform electromagnetic induction through a planar coil placed on a PCB and utilize a magnetic core structure to adjust the intensity of the electromagnetic induction, which in turn provides an output signal to drive a resonant assembly and generates the corresponding electromagnetic field to heat powder to be heated. The specific realization of the transformer 330 can be found elsewhere in the present disclosure, such as in FIG. 13 to FIG. 15B, FIG. 16B, and the related descriptions thereof.

In some embodiments, the high-frequency power supply 300 may further include a rectifier device. The rectifier device may be connected to an external power source and may be configured to rectify a received three-phase electrical signal to output a DC signal to the DC voltage regulator 310. In some embodiments, the rectifier device may include an electromagnetic interference filter and a three-phase rectifier bridge. The electromagnetic interference filter may filter the received three-phase electrical signal to reduce electromagnetic interference brought about by the external environment, and the three-phase rectifier bridge may convert the three-phase electrical signal into the DC signal.

In some embodiments, the high-frequency power supply 300 may further include a processor and a sampler. The processor may be configured to control the operation of members (e.g., the DC voltage regulator 310, the power device 320, and the transformer 330) as well as to process data. The sampler may sample an output signal provided by the high-frequency power supply 300 and send a sampled signal to the processor so that the processor may adjust the operation state of the device. In some embodiments, the high-frequency power supply 300 may further include a fuse. The fuse may monitor the outputs of a plurality of members in the high-frequency power supply 300 (e.g., the DC voltage regulator 310, the power device 320, and the transformer 330), to avoid over-current, over-voltage, over-text, over-frequency, or undervoltage of the devices, and to ensure that the members operate properly.

In some embodiments, the high-frequency power supply 300 may further include a capacitive isolation driver circuit. The capacitive isolation driver circuit may be used to isolate the processor from other members in the high-frequency power supply 300 (e.g., the DC voltage regulator 310, the power device 320, and the transformer 330), utilizing capacitive isolation to separate high-voltage transmission from low-voltage control.

Some embodiments are provided below to describe in detail specific implementations of the DC voltage regulator 310, the power device 320, and the transformer 330.

FIG. 6 is a schematic diagram illustrating an exemplary structure of a DC voltage regulator 310 according to some embodiments of the present disclosure. As shown in FIG. 6, in some embodiments, the DC voltage regulator 310 may include a plurality of DC voltage regulator modules 311 connected in parallel, an input terminal of each of the plurality of DC voltage regulator modules 311 receives a signal to be regulated, and there is a time delay between the signals to be regulated received by different DC voltage regulator modules 311, and an output terminal of the plurality of DC voltage regulator modules 311 connected in parallel outputs a target regulated signal, and the target regulated signal is a superposition of regulated signals output by each of the plurality of DC voltage regulator modules 311.

The DC voltage regulator module 311 refers to a circuit module that provides a stable DC signal despite fluctuations in the input grid voltage or changes in the load. In some embodiments, the plurality of DC voltage regulator modules 311 may be connected in parallel with phase-shifted signals, such that each of the plurality of DC voltage regulator modules 311 receives the same waveform of the signal to be regulated but with a timing difference. Due to the presence of certain noise and/or ripple in the signal to be regulated, in some embodiments, each DC voltage regulator module 311 may filter one signal to be regulated, removing a certain amount of noise and/or ripple, and outputting a regulated signal. In some embodiments, there may be a time delay between the signals to be regulated received by different DC voltage regulator modules 311, and thus there may be the same time delay between the regulated signals output by different DC voltage regulator modules 311. Since a switching member is usually used in the DC voltage regulator module 311 for filtering, a small portion of ripples may still exist in the regulated signals. By setting the time delay between different regulated signals, it is possible to make the ripples of a plurality of regulated signals misaligned when superimposed, which allows the ripples to cancel each other out, thereby obtaining the target regulated signal.

FIG. 7 is a schematic diagram illustrating a voltage regulation principle of a signal according to some embodiments of the present disclosure. As shown in FIG. 7, a first signal 710 may be a regulated signal 1, a second signal 720 may be a regulated signal 2, and a third signal 730 may be a target regulated signal. The presence of ripple results in a certain fluctuation of the first signal 710 and the second signal 720. A time delay To exists between the first signal 710 and the second signal 720, causing a ripple peak 711 of the regulated signal 1 to align in timing with a ripple valley 722 of the regulated signal 2, and a ripple valley 712 of the regulated signal 1 to align in timing with a ripple peak 721 of the regulated signal 2. When the first signal 710 and the second signal 720 are superimposed, the ripple peak 711 of the regulated signal 1 and the ripple valley 722 of the regulated signal 2 may cancel each other out, and the ripple valley 712 of the regulated signal 1 and the ripple peak 721 of the regulated signal 2 may cancel each other out, thereby obtaining the superimposed third signal 730.

In some embodiments of the present disclosure, a plurality of signals having time delays are received by a plurality of DC voltage regulator modules 311 at different levels, causing the ripples of a plurality of regulated signals to be misaligned and enabling ripple cancellation through the misalignment, thereby enhancing the stability of the target regulated signal.

In some embodiments, a time delay between signals to be regulated received by two adjacent DC voltage regulator modules 311 may be related to a signal at an output terminal of at least one DC voltage regulator module 311. Further, in some embodiments, the time delay between the signals to be regulated received by the two adjacent DC voltage regulator modules 311 may be related to a period of the signal at the output terminal of the DC voltage regulator module 311. To make ripple peaks and ripple valleys of two adjacent signals correspond in timing (as shown in FIG. 7), the positions of the ripple peaks and ripple valleys in timing may be adjusted according to a period of at least one signal. As shown in FIG. 7, the time delay T0 between the first signal 710 and the second signal 720 may be related to a period T of a regulated signal, and the time delay T0 may be an odd multiple of one-half of the period T.

In some embodiments, a ratio of the period of a signal at the output terminal of the plurality of DC voltage regulator modules 311 and a count of the plurality of DC voltage regulator modules 311 is correlated with the time delay. In some embodiments, the magnitude of the time delay is the same as the ratio of the period of the signal at the output terminal of the plurality of DC voltage regulator modules 311 and the count of the plurality of DC voltage regulator modules 311. For example, if there are 10 DC voltage regulator modules 311 connected in parallel, and the period of the signal at the output terminal of the plurality of DC voltage regulator modules 311 is 100 μs, then the delay time may be 10 μs, and the 1-th DC voltage regulator module 311 may start receiving the signal to be regulated at 0 s, the 2-th DC voltage regulator module 311 may start receiving the signal to be regulated at 10 μs, and so on, and the 10-th DC voltage regulator module 311 may start receiving the signal to be regulated at 90 μs, so that ripples the signals may be canceled out by the superposition of the 10 regulated signals.

In some embodiments, each DC voltage regulator module 311 may include a first voltage regulator circuit 312 and a second voltage regulator circuit 313. The first voltage regulator circuit 312 and the second voltage regulator circuit 313 are connected in series, and the first voltage regulator circuit 312 and the second voltage regulator circuit 313 have different efficiencies.

In some embodiments, each DC voltage regulator module 311 may include one or more voltage regulator circuits. In some embodiments, the voltage regulator circuit may be a combination of one or more circuits including a Buck circuit, an LLC circuit, a BOOST circuit, or the like. The efficiency of the voltage regulator circuit may reflect a comparative relationship between the output power of the voltage regulator circuit and the loss power of the voltage regulator circuit, and a higher efficiency of the voltage regulator circuit reflects a higher output power of the voltage regulator circuit and a lower loss power, and a lower efficiency of the voltage regulator circuit reflects a lower output power of the voltage regulator circuit and a higher power loss. The efficiencies of different voltage regulator circuits are different. For example, the efficiency of the Buck circuit may be lower than the efficiency of the LLC circuit. Besides, the stability of the voltage regulator circuit may reflect the performance of the voltage regulator circuit in suppressing ripple. A high stability indicates that the voltage regulator circuit is effective in suppressing ripple, whereas a low stability indicates that the voltage regulator circuit has poor performance in suppressing ripple. The stabilities of different regulator circuits are also different. For example, the stability of the LLC circuit is lower than the stability of the Buck circuit.

In some embodiments, when the DC voltage regulator module 311 includes the first voltage regulator circuit 312 and the second voltage regulator circuit 313, the first voltage regulator circuit 312 and the second voltage regulator circuit 313 may be connected in series in sequence, to filter and regulate the signal to be regulated several times, making the output of the DC voltage regulator module 311 more stable. In some embodiments, the first voltage regulator circuit 312 and the second voltage regulator circuit 313 may be coupled by a transformer, thereby realizing circuit isolation while being connected in series to reduce the mutual influence of signals.

In some embodiments, the first voltage regulator circuit 312 and the second voltage regulator circuit 313 may have different efficiencies, such that the first voltage regulator circuit 312 may be complementary with the second voltage regulator circuit 313 to ensure the overall efficiency of the DC voltage regulator module 311. In some embodiments, the first voltage regulator circuit 312 and the second voltage regulator circuit 313 may have different stabilities, such that the first voltage regulator circuit 312 may be complementary with the second voltage regulator circuit 313 to ensure the overall stability of the DC voltage regulator module 311. The first voltage regulator circuit 312 and the second voltage regulator circuit 313 may have different topologies so that the signal may be filtered and regulated using different filtering manners. For example, the first voltage regulator circuit 312 may use the Buck circuit, and the second voltage regulator circuit 313 may use the LLC circuit, with the Buck circuit being less efficient but more stable, and the LLC circuit being more efficient but less stable, so that a secondary voltage regulator circuit composed of the Buck circuit and the LLC circuit can have good stability and efficiency.

In embodiments of the present disclosure, by setting up multi-level voltage regulator circuits, it is possible for different voltage regulator circuits to complement each other, and various voltage regulation manners may be used to regulate the signal to be regulated multiple times, ensuring the overall stability and the efficiency of the DC voltage regulator module 311.

It should be noted that the first voltage regulator circuit 312 and the second voltage regulator circuit 313 are only for example, and the DC voltage regulator module 311 may further include two or more voltage regulator circuits, such as a third voltage regulator circuit, a fourth voltage regulator circuit, and a specific count of the voltage regulator circuit may be adjusted according to the filtering and voltage regulating effect demanded by the DC voltage regulator module 311.

An exemplary DC voltage regulator module 311 is provided below, detailing a specific realization of the first voltage regulator circuit 312 and the second voltage regulator circuit 313.

In some embodiments, the first voltage regulator circuit 312 is the Buck circuit, the second voltage regulator circuit 313 is the LLC circuit, an input terminal of the Buck circuit receives the signal to be regulated, an output terminal of the Buck circuit is connected to an input terminal of the LLC circuit, and an output terminal of the LLC circuit outputs a signal that has been regulated by the Buck circuit and the LLC circuit.

In some embodiments, the Buck circuit may control the conduction and cutoff of a switching member based on the comparison result between its output voltage and a reference voltage, thereby ensuring that the output voltage is close to the reference voltage and improving the stability of the output voltage. In some embodiments, the LLC circuit may control the conduction and cutoff of the switching member to switch the charging and discharging states of a resonant capacitor, thereby adjusting the gain provided by the LLC circuit to stabilize the output voltage. In some embodiments, the output terminal of the Buck circuit may be connected to the input terminal of the LLC circuit through a transformer, and the transformer may be used to isolate the circuit while transmitting signals to reduce signal interactions.

Correspondingly, in some embodiments, the DC voltage regulator module 311 may further include a control circuit 314. The control circuit 314 may be connected to the first voltage regulator circuit 312 and the second voltage regulator circuit 313, respectively, and may be configured to control the state of a member (e.g., the conduction and cutoff of the switching member), and may be configured to provide data (e.g., the reference voltage) for the voltage regulator circuit, or may be configured to perform processing and operation on data (e.g., comparing the output voltage and the reference voltage).

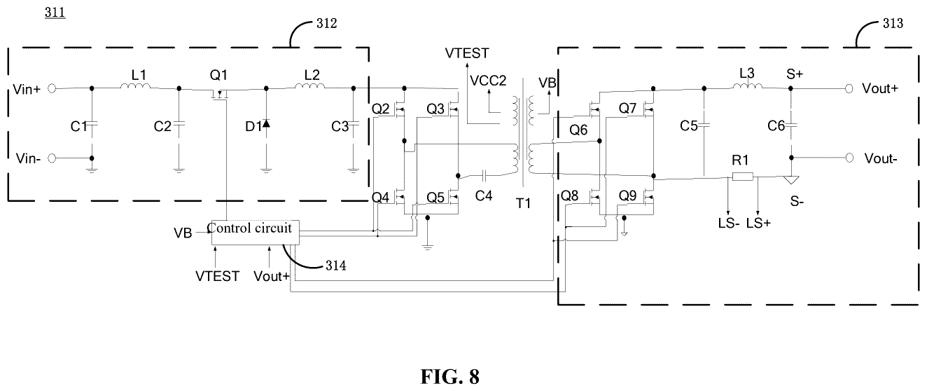

FIG. 8 is a schematic diagram illustrating a circuit of a DC voltage regulator module 311 according to some embodiments of the present disclosure. As shown in FIG. 8, the first voltage regulator circuit 312 may include capacitors C1 to C3, inductors L1 to L2, a switching member Q1, and a diode D1. Two ends of the capacitor C1 may be used as an input positive terminal Vin+ and an input negative terminal Vin−, respectively, for receiving a signal to be regulated. A first end of the capacitor C1 may be connected to one end of the capacitor C2 via the inductor L1, and another end of the capacitor C2 may be grounded. A connection point between the capacitor C2 and the inductor L1 may be connected to the source of the switching member Q1, the gate of the switching member Q1 is connected to the control circuit 314 for receiving a driving signal from the control circuit 314, the drain of the switching member Q1 is connected to the cathode of the diode D1, and the anode of the diode D1 is grounded. The cathode of the diode D1 is connected to one end of the capacitor C3 via the inductor L2, and another end of the capacitor C3 is grounded, and a regulated signal output by the first voltage regulator circuit 312 may be output from two ends of the capacitor C3.

In some embodiments, when an output voltage VTEST is lower than a reference voltage VB, the control circuit 314 may control the switching member Q1 to conduct, charging the capacitor C3 while increasing the voltage of an output signal. When the output voltage VTEST is larger than the reference voltage VB, the control circuit 314 may control the switching member Q1 to cut off, allowing the capacitor C3 to discharge while decreasing the voltage of the output signal, so that the voltage of the output signal is close to the reference voltage VB.

In some embodiments, an output terminal of the first voltage regulator circuit 312 may be connected to an input terminal of an inverter circuit (such as a bridge circuit composed of switching members Q2 to Q5 as shown in FIG. 8). An output terminal of the inverter circuit is connected to the primary side of a transformer T1 via a capacitor C4, the secondary side of the transformer T1 may be connected to an input terminal of the second voltage regulator circuit 313, and the gates of the bridge circuit composed of the switching members Q2 to Q5 are all connected to the control circuit 314, and the bridge circuit cooperates with the transformer T1 to transmit a signal to the second voltage regulator circuit 313. In some embodiments, the control circuit 314 may collect the output voltage VTEST from the primary side of the transformer T1, and the primary side of the transformer T1 may also provide a power supply VCC2 to power the control circuit 314.

In some embodiments, the second voltage regulator circuit 313 may include switching members Q6 to Q9, capacitors C5 to C6, a resistor R1, and an inductor L3. The drain of the switching member Q6 may be connected to the source of the switching member Q8 and connected to an output terminal on the secondary side of the transformer T1, and the drain of the switching member Q7 may be connected to the source of the switching member Q9 and connected to an input terminal on the secondary side of the transformer T1. The drains of the switching members Q8 to Q9 are connected to a reference negative pole S−, and the sources of the switching members Q6 to Q7 are connected to one end of the capacitor C5, and the sources of the switching members Q6 and Q7 are also connected to a reference positive pole S+ and one end of capacitor C6, respectively, via the inductor L3. Another end of the capacitor C5 is connected to the source of the switching member Q9, and is also connected to the reference negative terminal S− and another end of the capacitor C6 via the resistor R1, respectively. Two ends of the capacitor C6 may be used as an output positive pole Vout+ and an output negative pole Vout−, respectively, for outputting a signal that has been regulated by the first voltage regulator circuit 312 and the second voltage regulator circuit 313. In some embodiments, the control circuit 314 may also collect a signal that has been regulated by the output positive pole Vout+, so to regulate the operation state of the second voltage regulator circuit 313.

In some embodiments, when the second voltage regulator circuit 313 operates in an LLC resonant state (e.g., the inductor L3, the resistor R1, and the capacitor C5 are resonant), the switching members Q6 to Q9 may realize the soft switching, thereby reducing the switching losses. When the output voltage at the two ends of capacitor C6 changes, the switching frequency of the switching members Q6 to Q9 may be adjusted in such a way as to stabilize the voltage divided between the capacitor C5 and the inductor L3, thereby maintaining the stability of the voltage at the two ends of capacitor C6.

In some embodiments, the control circuit 314 of the DC voltage regulator 310 may be a module in a processor of the high-frequency power supply 300, or it may be set up separately from the processor. In some embodiments, the transformer T1 differs from the transformer 330 in structure and function, with the primary side of the transformer T1 being connected to the first voltage regulator circuit 312, and the secondary side being of the transformed T1 being connected to the second voltage regulator circuit 313, and the transformer T1 being used to transmit a signal between the first voltage regulator circuit 312 and the second voltage regulator circuit 313. The primary side of the transformer 330 is connected to the power device 320, and the secondary side of the transformer 330 is configured to provide an output signal to the resonant assembly 200, and the transformer 330 may be used to change the nature of an AC electrical signal (e.g., voltage).

In some embodiments, input ends of a plurality of DC voltage regulator modules 311 connected in parallel are connected to a rectifier circuit, and the rectifier circuit may rectify an external power supply to provide the plurality of DC voltage regulator modules 311 connected in parallel with signals to be regulated, respectively. An output terminal of the plurality of DC voltage regulator modules 311 connected in parallel are connected to the power device 320 to provide the power device 320 with a target regulated signal to enable the power device 320 to generate an electrical signal at a target AC frequency.

FIG. 9 is a block diagram illustrating an exemplary structure of a power device according to some embodiments of the present disclosure. As shown in FIG. 9, the power device 320 applied to a high-frequency power supply may include multi-level power modules 321, a controller 322, and an output terminal 323.

The multi-level power modules 321 are coupled to the controller 322 and the output terminal 323, respectively. The power module 321 at each level in the multi-level power modules 321 is configured to generate an electrical signal at a preset AC frequency.

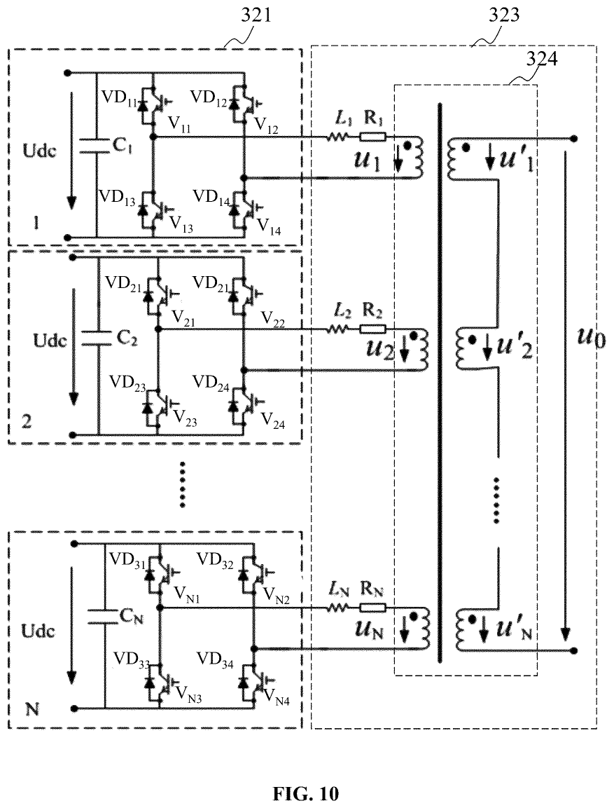

The power module 321 refers to a circuit module that performs signal conversion. In some embodiments, the power module 321 may be used to convert an input DC signal to the electrical signal at the preset AC frequency. In some embodiments, the power module 321 may include a combination of one or more of the following circuit structures: a single-ended inverter circuit, a half-bridge inverter circuit, a full-bridge inverter circuit, and a push-pull bridge inverter circuit. The specific realization of the power module 321 can be referred to in other descriptions in the present disclosure, such as FIG. 10 and the related descriptions thereof.

In some embodiments, the multi-level power modules 321 may include three-level power modules 321, five-level power modules 321, ten-level power modules 321, or the like. In some embodiments, a count of levels of the multi-level power modules 321 may be determined based on a desired output power and/or a target AC frequency of the power device 320. In some embodiments, the power module 321 at each level in the multi-level power modules 321 may be connected to each other in parallel. For example, an input terminal of the power module 321 at each level may be used to receive the DC signal, and an output loop of the power module 321 at each level may be coupled to the output terminal 323, respectively, thereby realizing that the power module 321 at each level is connected in parallel.

FIG. 10 is a schematic diagram illustrating an exemplary circuit structure of the power device 320 according to some embodiments of the present disclosure. As shown in FIG. 10, a power module 1, a power module 2, . . . , and a power module N included in the multi-level power modules 321 are coupled into a total output at the output terminal 323. In some embodiments, when the output terminal 323 includes a transformer 324, an output loop of the power module 312 at each level in the multi-level power modules 321 (e.g., the power module 1, the power module 2, . . . , and the power module N) may be provided at the primary side of the transformer 324, and the output loop of the power module 312 at each level may transmit an electrical signal at a preset AC frequency to the transformer 324, so that the output terminal 323 may generate an electrical signal at a target AC frequency. Further, the electrical signal at the target AC frequency may be used to drive a resonant assembly to generate a corresponding electromagnetic field, thereby heating powder to be heated.

In embodiments of the present disclosure, the parallel connection of the multi-level power modules 321 allows for current division across the circuits where the power module 321 at each level is located, reducing the current stress each module needs to withstand, increasing the flexibility in module selection, and lowering the circuit cost. Or, the parallel connection of the multi-level power modules 321 lowers the requirement for an inductor in the output loop of the power module 321, thereby reducing the ripple of the power module 321.

In some embodiments, the preset AC frequency may be a frequency corresponding to an operation cycle of the power module 321. The operation cycle may include a phase where the power module 321 is in an operation state and/or a phase where the power module 321 is in a non-operation state. For example, when the power module 321 is in the operation state during the 1 s and outputs a sine wave signal, and is in the non-operation state from the 2 s to 10 s, which corresponds to output a signal with a level of 0, then the operation cycle of the power module 321 may be 10 s, and the preset AC frequency of an electrical signal output by the power module 321 may be 0.1 Hz.

In some embodiments, the preset AC frequency may be a value of an AC frequency set according to system requirements. In some embodiments, the preset AC frequency may be a desired AC frequency for the power module 321 at each level.

In some embodiments, electrical signals generated by the power module 321 at each level in the multi-level power modules 321 may have the same AC frequency. That is, a plurality of electrical signals may have the same preset AC frequency. For example, the multi-level power modules 321 may be three-level power modules 321, and the power module 321 at each level in the three-level power modules 321 generates an electrical signal with the same preset AC frequency, i.e., the AC frequencies of the three electrical signals generated may be the same.

In some embodiments, there are at least two of the electrical signals generated by the multi-level power modules 321 that have different AC frequencies. That is, the plurality of electrical signals may have different preset AC frequencies. For example, the multi-level power modules 321 may be four-level power modules 321, and the power module 321 at each level in the multi-level power modules 321 generates an electrical signal with a preset AC frequency. Of four electrical signals generated, it may be that two of the power modules 321 (e.g., a first-level power module and a second-level power module) produce two electrical signals with different AC frequencies, or it may be that three of the power modules 321 (e.g., the first-level power module, the second-level power module, and a fourth-level power module) produce three electrical signals with different AC frequencies, or it may be that all of the four electrical signals have different AC frequencies.

It should be noted that in some embodiments, when at least two electrical signals have different AC frequencies, at least two of the electrical signals generated by the multi-level power modules 321 may also have the same AC frequency. That is, the plurality of electrical signals may have the same preset AC frequency or may have different preset AC frequencies. Continuing to illustrate with the above example of the four-level power modules 321, of the four electrical signals, it may be that two of the electrical signals generated by the first-level power module and the second-level power module have different AC frequencies, while the second-level power module, the third-level power module, and the fourth-level power module generate three electrical signals with the same AC frequency.

The target AC frequency may be a frequency value set by the power device 320 based on system requirements, which is equivalent to the frequency of an electromagnetic field generated by a resonant assembly. In some embodiments, the target AC frequency may be a desired AC frequency of the power device 320. Since the power module 321 at each level are connected in parallel, in some embodiments, the target AC frequency is related to a preset AC frequency of the power module at each level. The preset AC frequency of the electrical signal generated by the power module 321 at each level may be determined based on a determined target AC frequency. In some embodiments, the preset AC frequency of the power module at each level in the multi-level power modules 321 may be no less than 1 MHZ, and the target AC frequency may be no less than 4 MHz.

In some embodiments, the power module 321 may be a gallium nitride power module. The gallium nitride power module may include a gallium nitride transistor. In the gallium nitride (GaN) transistor, two materials with different bandgaps (e.g., aluminum gallium nitride (AlGaN) and gallium nitride (GaN)) are used. Conductivity is achieved through a two-dimensional electron gas (2DEG) formed at the interface of these materials due to the piezoelectric effect. Compared to traditional silicon transistors, the two-dimensional electron gas (2DEG) in gallium nitride (GaN) transistors requires a high electron concentration to conduct. As a result, GaN transistors are less prone to minority carrier recombination, which leads to reverse recovery in transistors, thus offering higher stability.

Furthermore, due to the wide bandgap and high critical electric field strength of gallium nitride (GaN) material, power semiconductors fabricated from GaN (such as GaN transistors) exhibit characteristics such as high breakdown voltage, low on-resistance, and minimal parasitic parameters. When gallium nitride (GaN) transistors are applied in the field of switching power supplies, they can reduce power device losses and increase operating frequency and reliability, thereby enhancing the efficiency, power density, and overall reliability of the switching power supply.

In some embodiments, the output terminal 323 may be coupled to the power module 321 at each level in the multi-level power modules 321, respectively, for generating the electrical signal at the target AC frequency based on the operation state of the multi-level power modules 321. At this time, the target AC frequency is related to the preset AC frequency of the power module at each level. In some embodiments, the output terminal 323 may include a signal aggregation component that may be applied to an electrical signal output by the multi-level power modules 321. As shown in FIG. 10, the signal aggregation component may be the transformer 324, and the primary side of the transformer 324 is provided with output loops of the power modules 321 at different levels (e.g., the power module 1, the power module 2, . . . , and the power module N), and the transformer 324 may integrate a plurality of electrical signals at a preset AC frequency output by the power modules 321 at different levels in the multi-level power modules 321, and generate the electrical signal at the target AC frequency on the output side of the transformer 324. That is, the transformer 324 may integrate a plurality of electrical signals into a single electrical signal.

A controller may be an electronic device that processes data. In some embodiments, the controller 322 may be used to control the operation state of one or more power modules 321 in the multi-level power modules 321. For example, the controller 322 may control the conduction and cutoff of a switching member in the power module 321 to cause the power module 321 to generate an AC electrical signal. In some embodiments, the controller 322 may regulate a switching frequency of the conduction and cutoff of the switching member to cause the power module 321 at each level to generate the AC electrical signal at the preset AC frequency. For example, the controller 322 may control the conduction and cutoff of the gallium nitride transistors in the gallium nitride module and adjust the switching frequency of the conduction and cutoff such that the gallium nitride module generates electrical signals at a preset AC frequency.

The operation state of the multi-level power modules 321 refers to the operation state of the power module at each level in the multi-level power modules 321. In some embodiments, when the power module 321 is in an operation state, the power module 321 may output an electrical signal, and when the power module 321 is in a non-operation state, the power module 321 does not output an electrical signal or output an electrical signal with a level of 0. In some embodiments, the power module 321 generating the electrical signal at the preset AC frequency includes an electrical signal generated by the power module 321 in the operation state, and an electrical signal that is not outputted or an electrical signal with a level of 0 in the non-operation state. That is, the switching of the power module 321 between the operation state and the non-operation state can generate the electrical signal at the preset AC frequency.

In some embodiments, the operation state of the power module 321 may be controlled by the controller 322. The controller 322 may control the power module 321 at each level in the multi-level power modules 321 to be in the operation state at the same time, may control the power module 321 at each level in the multi-level power modules 321 to be in the operation state during different periods, respectively, and may also control a portion of power modules 321 in the multi-level power modules 321 to be in the operation state at the same time and a portion of power modules 321 in the multi-level power modules 321 to be in the operation state during different periods, respectively.

For example, as shown in FIG. 10, in some embodiments, the controller 322 may control the multi-level power modules 321 to operate simultaneously. For example, the controller 322 may control the power module 1, the power module 2, . . . , and the power module N to be in the operation state at the same time, or the power module 1, the power module 2, . . . , and the power module N to be in the non-operation state at the same time.

In some embodiments, the controller 322 may control the multi-level power modules 321 to be in the operation states during different periods, respectively. For example, the controller 322 may control the power module 1 to be in the operation state during a first period (e.g., during the first 1 s) and in the non-operation state during the rest of the period. The controller 322 may control the power module 2 to be in the operation state during a second period (e.g., during the first 2 s) and in the non-operation state during the rest of the period. The controller 322 may control the power module N to be in the operation state during an N-th period (e.g., during the first N-th s) and in the non-operation state during the rest of the period.

In some embodiments, the controller 322 may control a portion of power modules 321 in the multi-level power modules 321 in the operation state at the same time and a portion of power modules 321 in the multi-level power modules 321 in the operation state during different periods, respectively. For example, the controller 322 may control the power module 1 and the power module 2 to be in the operation state during the first period (e.g., during the first 1 s) and in the non-operation state during the rest of the period. As another example, the controller 322 may control a power module 3 and a power module 4 to be in the operation state during the second period (e.g., during the first 2 s) and in the non-operation state during the rest of the period. In this way, the power module 1 and the power module 2 may operate at the same time, the power module 3 and the power module 4 may operate at the same time, and the combination of the power module 1 and the power module 2 and a combination of the power module 3 and the power module 4 may operate during different periods, respectively, thereby realizing the interleaved parallel connection of the multi-level power modules 321.

It is to be understood that a count of levels of the multi-level power modules 321 and the duration of the plurality of periods are only exemplary, and that the count of levels of the multi-level power modules 321 may be determined based on the desired output power and/or the target AC frequency of the power device 320 and the duration of the plurality of periods may also be determined based on a signal cycle, and a specific determination manner can be found elsewhere in the present disclosure.

In some embodiments, the power of the electrical signal generated at the output terminal 323 may be the same as the sum of powers output by the multi-level power modules 321. That is, the output power of the power device 320 may be the same as the sum of powers output by the multi-level power modules 321. Further, in some embodiments, the power of the electrical signal generated at the output terminal 323 may be the same as the sum of powers output by the power modules 321 that are in the operation state. For example, in FIG. 10, when the power module 1 and the power module 2 are in the operation state and other power modules (e.g., the power module 3, . . . , and the power module N) are in the non-operation state, the power of the electrical signal generated at the output terminal 323 is the same as the sum of powers output by the power module 1 and the power module 2.

In the embodiment of the present disclosure, in the case where the desired output power of the power device 320 remains unchanged, by setting up the multi-level power modules 321 connected in parallel, the output power that needs to be reached by the power module 321 at each level can be reduced, thereby increasing the flexibility in module selection.

In some embodiments, the controller 322 may control the power module 321 at each level in the multi-level power modules 321 to be in the operation state during different periods, respectively. At this time, the sum of the preset AC frequencies of the power module 321 at each level is the same as the target AC frequency.

In some embodiments, the different periods refer to uniformly distributed periods, e.g., uniformly distributed periods with a duration of 1 μs, 100 μs, 100 ms, and 1 s. In some embodiments, the different periods also refer to non-uniformly distributed periods. In some embodiments, the power module 321 at each level in the multi-level power modules 321 may be in the operation state during different periods, respectively. That is, the power module 321 at each level in the multi-level power modules 321 may operate during different periods, outputting electrical signals during different periods, respectively, and by integrating a plurality of electrical signals at the output terminal 323, the plurality of electrical signals are continuously output during a plurality of periods, thereby achieving frequency integration and ensuring the sum of the preset AC frequencies is the same as the target AC frequency.

FIG. 11 is a schematic diagram illustrating integration of signals according to some embodiments of the present disclosure. As shown in FIG. 11, when a first-level power module, a second-level power module, and a third-level power module are in an operation state during a first period T1, a second period T2, and a third period T3, respectively, an electrical signal 1 may be an AC signal at a preset frequency of 1/T output by the first-level power module, an electrical signal 2 may be an AC signal at a preset frequency of 1/T output by the second-level power module; and an electrical signal 3 may be an AC signal at a preset frequency of 1/T output by the third-level power module, and an electrical signal 4 may be an output signal at a target AC frequency of 3/T output by the output terminal 323. The output terminal 323 may obtain the electrical signal 4 by integrating the electrical signal 1, the electrical signal 2, and the electrical signal 3, and the waveform of the electrical signal 4 is a superposition of the electrical signals 1 to 3. Since the waveforms of the electrical signals 1 to 3 are similar or identical, the electrical signal 4 may be regarded as having its amplitude repeat three times over a period T. In other words, the period of the electrical signal 4 may be T/3, and the target AC frequency may be 3/T. That is, the sum of preset AC frequencies of a power module at each level

$$( e . g . , \frac{1}{T} + \frac{1}{T} + \frac{1}{T} )$$

is equal to the target AC frequency 3/T.

In the embodiment of the present disclosure, in the case where the target AC frequency remains unchanged, the multi-level power modules 321 being in the operation state during different periods, respectively, enables the AC frequency of signals generated by the multi-level power modules 321 to be superimposed, thereby reducing the required preset AC frequency for the power module 321 at each level, thereby increasing the freedom of module selection and packaging, and facilitating the management and maintenance of a device. Besides, the multi-level power modules 321 may also reduce the ripple frequency in the power module 321 by increasing a count of levels, further reducing the overall ripple of the power device.

In some embodiments, a four-level power module 321 may be provided in the power device 320, and a power module at each level in the four-level power module 321 may have a preset AC frequency of not less than 1 MHz and a target AC frequency of not less than 4 MHz.

In some embodiments, a power module at each level in the multi-level power modules 321 may also operate at the same time, and the target AC frequency may be the same as the preset AC frequency of the power module at each level when the power module at each level is in an operation state at the same time. For example, in the case where the first-level power module, the second-level power module, and the third-level power module are in an operation state at the same time during a first period and are in a non-operation state at the same time during a second period, the output terminal 323 generates an electrical signal repeatedly changes in amplitude over time in a manner similar or identical to that of the electrical signals output by the first-level power module, the second-level power module, and the third-level power module, i.e., the target AC frequency may be the same as the preset AC frequency of the power module at each level.

In some embodiments, each gallium nitride module in the multi-level power modules 321 may include four gallium nitride transistors, a capacitor, an inductor, and a resistor. Two gallium nitride transistors form an output loop, a capacitor is connected in parallel with the two gallium nitride transistors, an inductor and a resistor are provided on the output loop, and the output loop is configured to generate an electrical signal. Continuing to refer to FIG. 10, taking a first-level gallium nitride module (such as the power module 1 shown in FIG. 10) as an example, the first-level gallium nitride module may include a gallium nitride crystal VD₁₁, a gallium nitride crystal VD₁₂, a gallium nitride crystal VD₁₃, and a gallium nitride crystal VD₁₄, a capacitor C₁, an inductor L₁, and a resistor R₁. The gallium nitride crystal VD₁₁ and the gallium nitride crystal VD₁₄ may constitute an output loop, and the gallium nitride crystal VD₁₂ and the gallium nitride crystal VD₁₃ may constitute an output loop. The capacitor C₁ is connected in parallel with the two gallium nitride transistors (e.g., with the gallium nitride crystal VD₁₁ and the gallium nitride crystal VD₁₄, or with the gallium nitride crystal VD₁₂ and the gallium nitride crystal VD₁₃), and the inductor L₁ and the resistor R₁ are provided on the output loop. An output loop 1 may be, in turn, the gallium nitride crystal VD₁₁, the inductor L₁, the resistor R₁, and the gallium nitride crystal VD₁₄, and an output loop 2 may be, in turn, the gallium nitride crystal VD₁₂, the resistor R₁, the inductor L₁, and the gallium nitride crystal VD₁₃, so that electrical signals generated by the output loops formed by two sets of gallium nitride crystals (e.g., the output loop 1 and the output loop 2) have different directions.

Continuing to refer to FIG. 10, when the gallium nitride module is in an operation state, a controller may first control the gallium nitride crystal VD₁₁ and the gallium nitride crystal VD₁₄ to conduct, and control the gallium nitride crystal VD₁₂ and the gallium nitride crystal VD₁₃ to cut off, so that the capacitor Ci provides a DC signal Udc for the output loop 1, and the output loop 1 generates a positive electric signal u₁ on the primary side of the transformer 324. Then the controller may control the gallium nitride crystal VD₁₂ and the gallium nitride crystal VD₁₃ to conduct, and control the gallium nitride crystal VD₁₁ and gallium nitride crystal VD₁₄ to cut off, so that the capacitor C₁ provides the DC signal Udc for the output loop 2, and the output loop 2 generates the negative electrical signal u₁ on the primary side of the transformer 324, thereby generating the AC electrical signal u₁ through the gallium nitride module.

In some embodiments, the transformer 324 may convert, by electromagnetic induction, the electrical signal u₁, an electrical signal u₂, . . . , and an electrical signal u_{N} generated by a plurality of gallium nitride modules into an electrical signal u′₁, an electrical signal u′₂, . . . , and an electrical signal u′_{N} that are connected in series, thereby integrating and generating an electrical signal uo₀. The structure and working principle of other gallium nitride modules can be referred to the relevant descriptions of the first-level gallium nitride module above, which will not be repeated here.

It should be noted that the transformer 324 differs from the transformer 330 described above in structure and function, and that the primary side of the transformer 324 is connected to the multi-level power modules 321, and the secondary side of the transformer 324 may be connected to the transformer 330, and that the transformer 324 may be used to integrate a plurality of AC electrical signals. The primary side of the transformer 330 is connected to the power device 320, and the secondary side of the transformer 330 is used to provide an output signal to the resonant assembly 200, and the transformer 330 may be used to change the nature of the AC electrical signal (e.g., the voltage, etc.).

In some embodiments, the controller may send a modulation signal to a driver module so that the driver module may control the conduction and cutoff of a switching member. Further, in some embodiments, the driver module may control two switching members in the same output loop such that the two switching members may be conducted and cut off simultaneously.

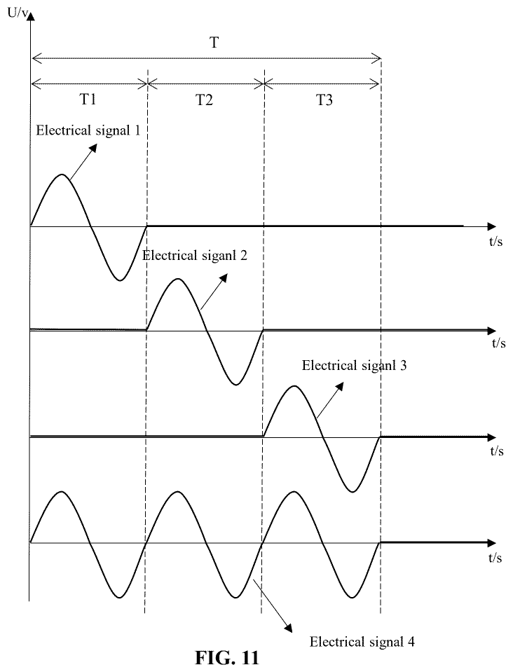

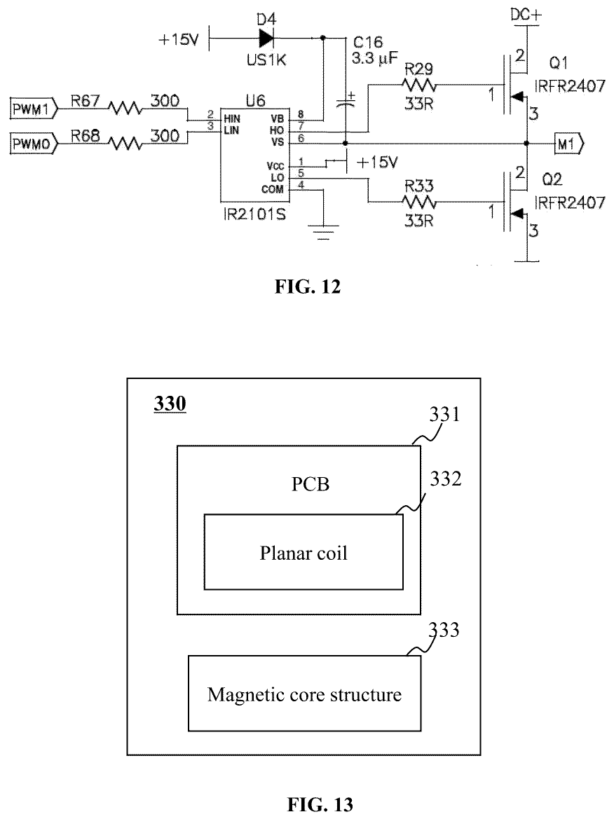

FIG. 12 is a schematic diagram illustrating an exemplary circuit structure of a driver module according to some embodiments of the present disclosure. In some embodiments, as shown in FIG. 12, the driver module may include a driver chip U6, and the driver module may receive two modulation signals PWM1 and PWM0 from a controller through a resistor R67 and resistor R68 (e.g., resistors with a resistance value of 300 ohms) and connect to a high-input terminal HIN and a low-input terminal LIN of the driver chip U6, respectively. A high-output terminal HO and a low-output LO of the driver chip U6 are connected to the gates of the Q1 and Q2 of a MOS tube (e.g., the gallium nitride crystal VD₁₁ and the gallium nitride crystal VD₁₄, or the gallium nitride crystal VD₁₂ and the gallium nitride crystal VD₁₃ as shown in FIG. 10) through a resistor R29 and resistor R33 (e.g., resistors with a resistance value of 33 ohms), respectively. A power supply terminal VS of the driver chip U6 provides a signal M1 and is connected to the source of Q1 and the drain of Q2 at the same time, and a power-supply receiving terminal VB of the driver chip U6 receives the +15V voltage through the forward conduction of the diode D4, and a power-supply input terminal VCC of the driver chip U6 receives the +15V voltage. A capacitor C16 (e.g., a capacitor with a capacitance of 3.3 uF) is connected to the cathode of the diode D4 at one end and to the power supply terminal VS of the driver chip U6 at the other end. A COM terminal of the driver chip U6 is grounded.

In some embodiments, a high-performance drive module may be used to ensure that a switching member operates in an optimal switching state, reducing switching time and minimizing switching losses. In some embodiments, some protection circuits can also be provided in the driver module, which can effectively improve the operational efficiency, reliability, and safety of the system.

In some embodiments, the power device 320 may adjust a target AC frequency of an electrical signal it outputs in response to a change in the scene. The change in the scene described herein may include variations in the load driven by the power device, changes in the temperature of the environment where the power device is located, or adjustments made by the user to the relevant parameters of the power device 320. Merely by way of example, the power device 320 may be used to adjust a target AC frequency of a generated electrical signal when a ratio of a reactive power of the high-frequency power supply 300 to the output power of the high-frequency power supply 300 exceeds a preset threshold. For example, when the ratio of the reactive power of the high-frequency power supply 300 to the output power of the high-frequency power supply 300 exceeds the preset threshold, the controller 322 may adjust a preset AC frequency of an electrical signal generated by the power module 321. The output power of the high-frequency power supply 300 may include reactive power and active power. The reactive power of the high-frequency power supply 300 may be the power consumed by a device that utilizes the principle of electromagnetic induction to transfer electrical energy (e.g., the power device 320, the transformer 330, the resonant assembly 200, etc.), i.e., the power consumed by the transmission of electrical energy.

In some embodiments, the reactive power may be affected by the material of powder to be heated. Since the powder to be heated may be used as the load of a heating device, the frequency at which the powder to be heated resonates with the heating device (hereinafter referred to as a resonant frequency) is different for different materials. When the material of the powder to be heated changes, it will result in a difference between the operation frequency (or the operation frequency of the high-frequency power supply 300) of the heating device and the resonant frequency, increasing the power consumed by transmitting the electrical energy (e.g., the reactive power of the high-frequency power supply 300), which in turn reduces the active power of the heating device and reduces the heating effect of the heating device for heating the powder to be heated. The operation frequency of the high-frequency power supply 300 and the operation frequency of the heating device are both controlled by the target AC frequency of the electrical signal output by the power device 320. In some embodiments, the ratio of the reactive power of the high-frequency power supply 300 to the output power of the high-frequency power supply 300 may be related to the heating effect of the heating device on the powder to be heated. For example, the preset threshold may be in a range of 5% to 15%. When the ratio of the reactive power of the high-frequency power supply 300 to the output power of the high-frequency power supply 300 exceeds the preset threshold, it may be determined that the heating device is less effective at heating the powder to be heated, and the controller 322 may adjust the preset AC frequency of the electrical signal generated by the power module 321 to adjust the target AC frequency of the electrical signal, so that the operation frequency of the heating device is close to or reaches the resonant frequency, and the reactive power of the high-frequency power supply 300 is reduced.

In some embodiments, the multi-level power modules 321 may be connected to the DC voltage regulator module 311, and the DC voltage regulator module 311 may be configured to provide a target regulated signal to the multi-level power modules. The output terminal 323 may be connected to the transformer 330, and the output terminal 323 provides an electrical signal at the target AC frequency to the transformer 330, enabling the transformer 330 to transform the electrical signal at the target AC frequency to generate an output signal.

FIG. 13 is a block diagram illustrating a transformer applied in a high-frequency power supply according to some embodiments of the present disclosure. As shown in FIG. 13, the transformer 330 may include a PCB (printed circuit board) 331, a planar coil 332, and a magnetic core structure 333. The PCB 331 may be used to carry the planar coil 332, so that the planar coil 332 is arranged around the magnetic core structure 333. The planar coil 332 may receive an alternating current signal and generate electromagnetic induction, so that the alternating current signal may be transmitted from one layer of the planar coil 332 to another layer of the planar coil 332, thereby realizing signal transmission. In some embodiments, the magnetic core structure 333 may adjust the intensity of the electromagnetic induction, thereby adjusting the parameters of the alternating current signal (e.g., the voltage and frequency of a signal), thereby realizing signal processing.

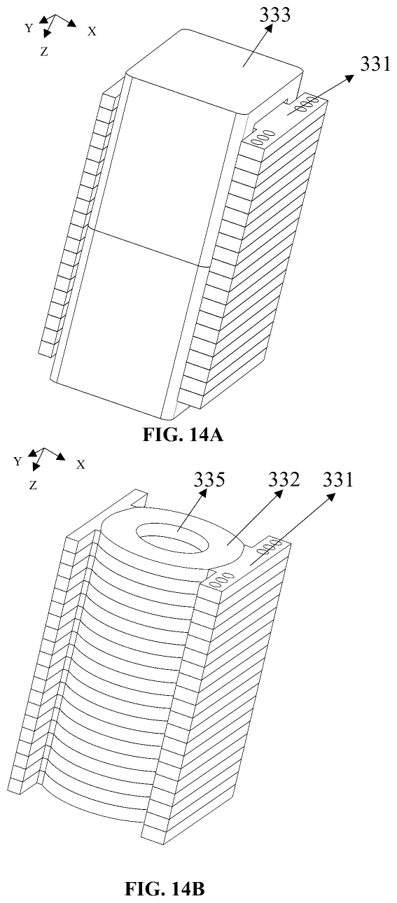

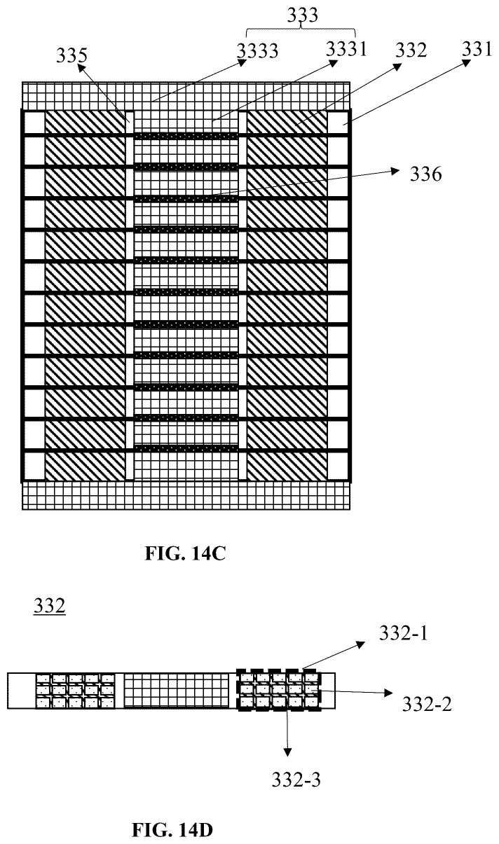

FIG. 14A is a schematic diagram illustrating a three-dimensional structure of a

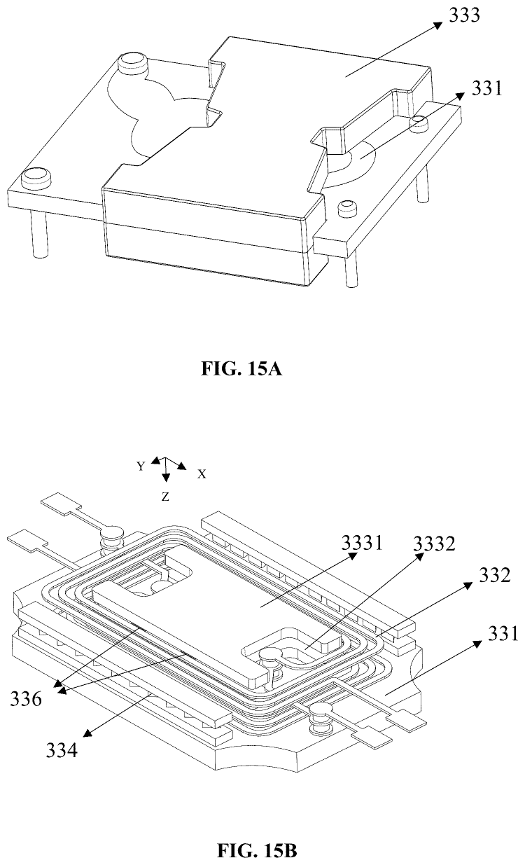

transformer according to some embodiments of the present disclosure. FIG. 14B is a schematic diagram illustrating a perspective view of a transformer according to some embodiments of the present disclosure. FIG. 14C is a schematic diagram illustrating a cross-sectional structure of a transformer according to some embodiments of the present disclosure. FIG. 14D is a schematic diagram illustrating a cross-sectional structure of one layer of a PCB according to some embodiments of the present disclosure. FIG. 15A is a schematic diagram illustrating a simplified structure of a transformer according to some embodiments of the present disclosure. FIG. 15B is a schematic diagram illustrating a simplified perspective view of a transformer according to some embodiments of the present disclosure.

As shown in FIG. 14A to FIG. 15B, in some embodiments, the transformer 330 may include a multi-layer PCB 331, a multi-layer planar coil 332, and a magnetic core structure 333. Each layer of the PCB 331 is provided with a hollow structure 335, and each layer of the planar coil 332 is fixed to one layer of the PCB 331 and disposed around the hollow structure 335. The magnetic core structure 333 may include a plurality of magnetic core plates, each of the plurality of magnetic core plates may be disposed within the hollow structure 335 of one layer of the PCB, and there is a spacing between two adjacent magnetic core plates (a first magnetic core plate 3331 and a second magnetic core plate 3332 as shown in FIG. 15B). As shown in FIG. 14A to FIG. 14B and FIG. 15B, in some embodiments, the magnetic core structure 333 may also include a magnetic core member 3333, and the magnetic core member 3333 may be sleeved on an outer side of the hollow structure 335, and the magnetic core member 3333 may be used to enhance the magnetic induction strength of the transformer 330.

The PCB is a support for electronic components. In some embodiments, the PCB 331 may include an insulating layer and a conductive layer, and a desired conductive circuit may be obtained by etching the conductive layer with a conductive material. Different conductive layers may be isolated by an insulating layer, and a conductive circuit (e.g., the planar coil 332) disposed between different conductive layers may be connected via a through-hole. In some embodiments, each layer of the PCB 331 is provided with the hollow structure 335 to dispose the planar coil 332 and a magnetic core board. In some embodiments, different layers of the PCB 331 may be overlapped, and different layers of the PCB 331 may be electrically isolated by the insulating layer in the PCB 331, or may be electrically isolated by being spaced a certain distance apart. In some embodiments, the multi-layer PCB 331 may be distributed along the thickness direction of the PCB 331. As shown in FIG. 14A to FIG. 14B and FIG. 15B, a three-dimensional coordinate system may be established with the length of the PCB as the X-axis, the width of the PCB as the Y-axis, and the thickness of the PCB as the Z-axis. The thickness direction of the PCB 331 may be the Z-axis direction of the three-dimensional coordinate system.

It should be noted that, in order to facilitate the description of the structure of the transformer 330, the multi-layer PCB 331 is simplified as two adjacent layers of the PCB as shown in FIG. 15B. However, in the embodiment of the present disclosure, a count of layers of the multi-layer PCB 331 is not limited to two, and the count of layers of the multi-layer PCB 331 may also be four, ten, sixteen, or twenty (as shown in FIG. 14A to FIG. 15B).

In some embodiments, as shown in FIG. 15B, the PCB may be provided with one or more pads 334, and each of the one or more pads 334 may be provided between two adjacent layers of the PCB 331 to separate the two adjacent layers of the PCB 331. The one or more pads 334 may separate two adjacent layers of the PCB 331 so that the contact surfaces of the two adjacent layers of the PCB 331 are not completely fitted together, so that the transformer 330 may dissipate heat through the gap between the two adjacent layers of the PCB 331. In some embodiments, two ends of each of the one or more pads 334 may contact the two adjacent layers of the PCB 331, respectively, and the one or more pads 334 may also be used to fix the positions of the two adjacent layers of the PCB 331.

The planar coil 332 may be a ring-shaped multi-turn windings. In some embodiments, the planar coil 332 may be arranged around the hollow structure 335 of the PCB so that the planar coil 332 may perform electromagnetic induction around the magnetic core structure 333. In some embodiments, the multi-turn windings of the planar coil 332 may be arranged on the same plane. As shown in FIG. 15A to FIG. 15B, the planar coil 332 may be a winding that surrounds a center point (e.g., the center point of the hollow structure 335) for multiple turns on the same plane (e.g., a plane parallel to the X-Y plane) to expand the heat dissipation area of the planar coil 332. In addition, since there is no current inside a conductor when an alternating current begins to pass through the conductor of the coil, the current is easily concentrated in a thin layer near the outer surface of the conductor, causing a skin effect, which easily increases the resistance and power loss of the coil, causing the coil to generate a large amount of heat energy.

Compared with a conventional coil winding (such as a single-layer coil centrally wound around an axis), the planar coil 332 in the present disclosure has a smaller thickness and a larger width on the plane, so that the skin effect area is close to the cross-sectional area of the wire, which can reduce the resistance of the coil while expanding the heat dissipation area of the planar coil 332, thereby minimizing the skin effect of the planar coil 332 and improving the power of the transformer 330.

In some embodiments, layers of the planar coil 1332 in the multi-layer planar coil 332 may be arranged on layers of the PCB in the multi-layer PCB, respectively, so that there is a spacing between different layers of the planar coil 332, which further widens the heat dissipation channel of the coil, thereby improving the efficiency of the transformer. In some embodiments, one or more layers of the planar coil 332 may be disposed on the same layer of the PCB, and one or more layers of the planar coil 332 on one layer of the PCB may be connected through a conductive circuit.

In some embodiments, at least two planar coils in the multi-layer planar coil 332 close to the primary side of the transformer 330 are connected in series, and at least two planar coils in the multi-layer planar coil 332 close to the secondary side of the transformer 330 are connected in parallel. The primary side of the transformer 330 is configured to receive an electrical signal at a target AC frequency from the power module 321, and the secondary side of the transformer 330 is configured to generate an output signal.

In some embodiments, a portion of planar coils 322 in the multi-layer planar coil 332 may be used as the primary side winding of the transformer to receive an AC signal (e.g., an electrical signal at a target AC frequency from a power device), and another portion of planar coils 322 in the multi-layer planar coil 332 may be used as the secondary side winding of the transformer to generate an output signal, which is used to drive the resonant assembly 200 to generate an alternating electromagnetic field. In addition, since the multi-layer planar coil 332 is arranged around the hollow structure 335, the planar coils 332 corresponding to the primary side winding may transmit the AC signal to the planar coils 332 corresponding to the secondary side winding through electromagnetic induction.

In some embodiments, the planar coils 332 corresponding to the same winding may be arranged on adjacent layers or on different layers. For example, the planar coils 332 corresponding to the primary side winding may include the first-layer planar coil 332, the second-layer planar coil 332, and the third-layer planar coil 332, or may include the first-layer planar coil 332, the second-layer planar coil 332, and the fifth-layer planar coil 332.

In some embodiments, the connection manner of the planar coils 332 corresponding to the same winding may be set according to a count of coil turns required by the winding. For example, since the voltage on the primary side of the transformer 330 is relatively small, more turns of the primary side winding are required, and the planar coils 332 corresponding to the primary side winding may be connected in series. As another example, since the voltage on the secondary side of the transformer 330 is relatively large, less turns of the primary side winding is required, and the planar coils 332 corresponding to the primary side winding may be connected in parallel.

Since the planar coil 332 has a good heat dissipation area, the power loss of the transformer 330 is small when the power and output frequency of the transformer remain unchanged, and the volume occupied by the transformer 330 can be reduced by reducing the thickness of the PCB 331 and the planar coil 332. In some embodiments, the thickness of each layer of the PCB 331 in the multi-layer PCB 331 is not more than 0.4 mm, and the thickness of each layer of the planar coil 332 in the multi-layer planar coil 332 is not more than 17 μm. Further, in some embodiments, the thickness of each layer of the PCB 331 in the multi-layer PCB 331 is not more than 0.2 mm.

In some embodiments, the operation frequency range of the transformer 330 may be in a range of 700 kHz to 4 MHz. Compared with conventional transformers, the transformer 330 may be used in a high-frequency scenario. In some embodiments, the ratio of a cable cross-sectional area of the multi-layer planar coil 1332 to the winding area of the multi-layer planar coil 332 is in a range of 80% to 90%. The winding area of the multi-layer planar coil 332 refers to the cross-sectional area occupied by the winding as a whole in the multi-layer planar coil 332, and the cable cross-sectional area in the multi-layer planar coil refers to the cross-sectional area of a plurality of turns of cables in the winding area. Since there is a certain gap between the plurality of turns of cables when the cable is wound in a coil, the winding area of the multi-layer planar coil 332 includes at least the cable cross-sectional area of the multi-layer planar coil 1332 and the area of gaps between the plurality of turns of cables.

For example, as shown in FIG. 14D, a plurality of layers of the planar coil 332 are provided on one layer of the PCB, the area corresponding to a frame region 332-1 may be the winding area of the planar coil 332 on one layer of the PCB, the area corresponding to each dotted region 332-2 may be the cross-sectional area of a cable, and the cross-sectional area of all cables in the frame region 332-1 (i.e., the sum of the areas of all dotted regions 332-2 on one layer of the PCB) may be the cable cross-sectional area of the planar coil 332 on the layer of the PCB, and a shaded region 332-3 may be gaps between a plurality of turns of cables in the planar coil on the layer of the PCB. On the same layer of the PCB, the gap between the plurality of turns of cables in the planar coil 332 may include gaps between cables on the same layer and gaps between cables on different layers, i.e., gaps between two adjacent layers of the planar coil 332. In the transformer 330, the winding area of the multi-layer planar coil 332 may be the area of all the frame regions 332-1 in the multi-layer planar coil 332 and the areas of the gaps between all two adjacent layers of the PCB, and the cable cross-sectional area of the multi-layer planar coil 332 may be the area of all the dotted regions 332-2 in all the frame regions 332-1.

In some embodiments, the ratio of the cable cross-sectional area of the multi-layer planar coil 332 to the winding area of the multi-layer planar coil 332 is also used as a window utilization rate. In some embodiments, the window utilization rate may be the cross-sectional area of a plurality of turns of cables that can be wound in a unit size of the winding area, and the window utilization rate may be used to measure the heat loss of the transformer. The higher the window utilization rate, the lower the heat loss of the transformer, and the lower the window utilization rate, the higher the heat loss of the transformer.

Compared with a conventional coil winding, the planar coil 332 in the present

disclosure can wrap more turns of cables in a unit winding area, so that the cross-sectional area of a plurality of turns of cables is larger, so that the window utilization rate of the planar coil 332 is higher, reducing the heat loss of the transformer.

FIG. 16A is a schematic diagram illustrating temperature field effect of an existing transformer; FIG. 16B is a schematic diagram illustrating temperature field effect of the transformer 330 according to some embodiments of the present disclosure. As shown in FIG. 16A, a coil of the existing transformer is a single-layer winding with an iron core as an axis, and the temperature of the coil in a first region 1631 (as shown in FIG. 16A, dots in the first region 1631 are sparser, indicating a lower temperature) is lower than the temperature of the coil in a second region 1632 (as shown in FIG. 16A, dots in the second region 1632 are denser, indicating a higher temperature). In other words, the temperature distribution of the coil of the existing transformer is uneven. Moreover, the maximum temperature of the transformer shown in FIG. 16A during operation is 90 degrees Celsius.

As shown in FIG. 16B, in a third region 1633, the temperature of the PCB 331 and the temperature of the planar coil 332 provided in the embodiment of the present disclosure are evenly distributed (as shown in FIG. 16B, dots in the third region 1633 are evenly distributed). In addition, the maximum temperature of the transformer shown in FIG. 16B during operation is 60 degrees Celsius.

It can be seen that a coil 1630 of the existing transformer 330 is a single-layer coil with an iron core as an axis. A projected heat dissipation area of the coil 1630 is small, and the skin effect is easy to occur while conducting electricity, which greatly increases the resistance and power loss of the coil, so that the coil 1630 may generate a large amount of heat energy and face difficulty in heat dissipation. Compared with the traditional coil 1630, the planar coil 332 provided in the embodiment of the present disclosure has a larger projected heat dissipation area, and can dissipate heat through the PCB 331, expanding the heat dissipation channel of the planar coil 332 while reducing the resistance of the coil, thereby reducing the skin effect of the planar coil 332 and improving the power of the transformer 330.

In some embodiments, there is a corresponding relationship between the area and the shape of the planar coil 332 and the maximum operation voltage and the maximum operation current of the transformer 330. In some embodiments, the maximum operation voltage of the transformer 330 is related to a spacing between cables of the planar coil 332. For example, the larger the spacing between a plurality of cables, the larger the maximum operation voltage of the transformer 330, and the larger the spacing between coils. For example, the spacing between cables of the planar coil 332 may be 0.1 mm, and the maximum operation voltage of the transformer 330 may be 100 V. In some embodiments, the maximum operation current of the transformer 330 is related to the thickness and the radial dimension of the planar coil 332. The radial dimension of the planar coil 332 refers to the shortest distance between the outermost winding and the innermost winding of the planar coil. In some embodiments, the planar coil 332 may be a thick copper plate, and the larger the area or the larger the thickness, the larger the current the planar coil 332 can carry, and the larger the maximum operation current of the transformer 330. For example, the thickness of the planar coil 332 may be 5 oz, and the radial dimension (i.e., diameter) of the planar coil 332 may be 1 mm, and the maximum operation current of the transformer 330 may be 5 A.

In some embodiments, as shown in FIG. 14A to FIG. 15B, the magnetic core structure 333 may include a plurality of magnetic core plates, each of the plurality of magnetic core plates is disposed within a hollow structure of each layer of the PCB, and there is a spacing between two adjacent magnetic core plates (a first magnetic core plate 3331 and a second magnetic core plate 3332). Since the planar coil 332 may generate a magnetic field through electromagnetic induction, the magnetic core plate may be magnetized in the magnetic field, thereby enhancing the effect of electromagnetic induction and changing the voltage of the AC signal transmitted by the planar coil 332.

In some embodiments, as shown in FIG. 14C and FIG. 15B, the magnetic core structure 333 may include one or more air gaps 336. In some embodiments, the air gap 336 may be provided between two adjacent magnetic core plates to separate the two adjacent magnetic core plates (e.g., the first magnetic core plate 3331 and the second magnetic core plate 3332 shown in FIG. 15B).

The air gap 336 refers to an air gap provided in the magnetic core structure 333, which may be used to separate the first magnetic core plate 3331 and the second magnetic core plate 3332 that constitute the magnetic core structure 333, so that contact surfaces between the first magnetic core plate 3331 and the second magnetic core plate 3332 are not completely attached together, so as to facilitate the heat dissipation of the transformer 330 through the gap between the first magnetic core plate 3331 and the second magnetic core plate 3332. In some embodiments, the height of the air gap may be in a range of 0.1 mm to 0.3 mm.

In some embodiments, the material of the magnetic core structure 333 may be PC200 ferrite. The maximum operation frequency of conventional ferrite and amorphous, ultra-microcrystalline and other transformers is usually below 400 KHz, e.g., the maximum operation frequency of a transformer made of a PC95 ferrite material may be 300 KHz. However, compared with conventional materials such as PC95 and PC47, the heat loss distribution of PC200 ferrite is more uniform, so that the magnetic core structure 333 made of the PC200 ferrite in the embodiment of the present disclosure is featured by high frequency, low loss, high efficiency, high energy saving, etc., thereby improving the power and frequency of the transformer 330.

In some embodiments, the operation frequency of the transformer may be in a range of 700 kHz to 4 MHz. When the switching frequency is in a range of 1.8 MHz to 2 MHz and the operation temperature is 100 degrees, the transformer 330 with the magnetic core structure 333 made of the PC 200 ferrite can achieve maximum transmission power.

In some embodiments, there is a corresponding relationship between the cross-sectional area of each magnetic core plate in the magnetic core structure 333 and a count of turns of the multi-layer planar coil 332. In some embodiments, the corresponding relationship between the cross-sectional area of each magnetic core plate and the count of turns of the multi-layer planar coil 332 may be an inverse relationship. Since the cross-sectional area of the magnetic core plate is proportional to the electromagnetic induction effect, the count of turns of the planar coil 332 is also proportional to the electromagnetic induction effect. When the electromagnetic induction effect of the transformer 330 remains unchanged, the cross-sectional area of the magnetic core plate and the count of turns of the multi-layer planar coil 332 may be inversely proportional. For example, the corresponding relationship between the cross-sectional area of the magnetic core plate and the count of turns of the multi-layer planar coil 332 may be as shown in the following formula:

$$N = \frac{U}{4 F B S}$$

U denotes the voltage value output by the transformer 330, N denotes the count of turns of the multi-layer planar coil 332, F denotes the operation frequency of the transformer, B denotes the magnetic flux density of the magnetic field generated by the transformer 330, and S denotes the cross-sectional area of the magnetic core plate. That is, when the electromagnetic induction effect of the transformer 330 remains unchanged, the larger the cross-sectional area of the magnetic core plate, the fewer turns of the multi-layer planar coil 332 are required, and the smaller the cross-sectional area of the magnetic core plate, the more turns of the multi-layer planar coil 332 are required.

The transformer described in some embodiments of the present disclosure, by disposing the planar coil 332 on the PCB 331, so that under the same power and frequency output, the power consumption of the transformer is much lower than that of a conventional medium-frequency transformer, and the transformer may be used in high-frequency scenarios and the volume of the transformer is smaller.

The beneficial effects brought about by the embodiments of the present disclosure include but are not limited to:
(1) A high-frequency power supply provides a high-frequency signal to a resonant assembly, driving the resonant assembly to generate an electromagnetic field that directly acts on powder. This process heats the powder while reducing the energy transferred to a pot body, preventing the pot body from deforming or volatilizing due to heating, thereby enabling the heating of high-melting-point powder.
(2) DC voltage regulator modules at multiple levels receive a plurality of signals with a time delay, causing the ripples of regulated signals to be misaligned when superimposed, which enables the ripples to be canceled out, thereby enhancing the stability of a target regulated signal.
(3) By designing a multi-level power module connected in parallel, the circuits of the power module at each level can be distributed, reducing the current stress on the power module at each level and increasing flexibility in module selection while lowering circuit costs. Furthermore, the parallel connection between power modules at multiple levels reduces the inductance requirements in the output loop of the power modules, thereby minimizing the ripple output by the power device.
(4) In the transformer, by disposing the planar coil on the PCB, the skin effect area of the planar coil closely matches the cross-sectional area of the conductor, reducing the resistance of coil while increasing the heat dissipation area, thereby mitigating the skin effect of the planar coil and enhancing the power output of transformer 330. Additionally, under the same power and frequency output, the transformer consumes significantly less power than conventional medium-frequency transformers. Besides, the transformer may also be applied in high-frequency scenarios while maintaining a more compact volume.

The basic concepts have been described above, and it is apparent to those skilled in the art that the foregoing detailed disclosure serves only as an example and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe embodiments of the present disclosure, such as “one embodiment”, “an embodiment”, and/or “some embodiments” means a feature, structure, or characteristic associated with at least one embodiment of the present disclosure. Accordingly, it should be emphasized and noted that two or more references in the present disclosure, at different locations, to “one embodiment” “an embodiment” or “an alternative embodiment” in different places in the present disclosure do not necessarily refer to the same embodiment. In addition, certain features, structures, or characteristics of one or more embodiments of the present disclosure may be suitably combined.

Additionally, unless expressly stated in the claims, the order of the processing elements and sequences, the use of numerical letters, or the use of other names as described in the present disclosure are not intended to qualify the order of the processes and methods of the present disclosure. While some embodiments of the invention that are currently considered useful are discussed in the foregoing disclosure by way of various examples, it is to be understood that such details serve only illustrative purposes and that additional claims are not limited to the disclosed embodiments, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that in order to simplify the presentation of the present disclosure, and thereby aid in the understanding of one or more embodiments of the invention, the foregoing descriptions of embodiments of the present disclosure sometimes combine a variety of features into a single embodiment, accompanying drawings, or descriptions thereof. However, this method of disclosure does not imply that the objects of the present disclosure require more features than those mentioned in the claims. Rather, claimed subject matter may lie in less than all features of a single foregoing disclosed embodiment.

Some embodiments use numbers to describe the number of components, attributes, and it should be understood that such numbers used in the description of the embodiments are modified in some examples by the modifiers “about”, “approximately”, or “substantially”. Unless otherwise noted, the terms “about,” “approximately,” or “substantially” indicate that a ±20% variation in the stated number is allowed. Correspondingly, in some embodiments, the numerical parameters used in the specification and claims are approximations, which can change depending on the desired characteristics of individual embodiments. In some embodiments, the numerical parameters should consider the specified number of valid digits and employ general place-keeping. While the numerical domains and parameters used to confirm the breadth of their ranges in some embodiments of this specification are approximations, in specific embodiments, such values are set to be as precise as possible within a feasible range.

For each of the patents, patent applications, patent application disclosures, and other materials cited in the present disclosure, such as articles, books, specification sheets, publications, documents, etc., the entire contents of which are hereby incorporated herein by reference. Application history documents that are inconsistent with or conflict with the contents of the present disclosure are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and those set forth herein, the descriptions, definitions, and/or use of terms in the present disclosure shall prevail.

Finally, it should be understood that the embodiments described in the present disclosure are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A heating system, comprising:
a pot body configured to contain powder to be heated;
a high-frequency power supply configured to supply an output signal with a power of not less than 5 kw and a frequency of not less than 1 MHz; and
a resonant assembly configured to generate an electromagnetic field for directly heating the powder to be heated under driving of the output signal.

2. The heating system of claim 1, wherein the resonant assembly includes a first coil, the first coil is disposed at a bottom of the pot body, and the first coil generates the electromagnetic field under driving of the output signal.

3. The heating system of claim 1, wherein the resonant assembly includes a second coil, and the second coil is disposed around the pot body.

4. The heating system of claim 1, wherein a temperature field generated by the electromagnetic field for heating the powder to be heated includes a first temperature and a second temperature, the first temperature is a temperature at a position affixed to the pot body, and the second temperature is a temperature at a preset distance from the pot body, the first temperature being less than the second temperature.

5. The heating system of claim 1, wherein the powder to be heated includes one or more of lutetium yttrium oxyorthosilicate (LYSO), gallium aluminum garnet, yttrium aluminum garnet, aluminum oxide crystal, lithium tantalate crystal, lithium niobate crystal, barium borate crystal, lithium triborate crystal, or a doped crystal including one or more elements from metal elements or transition elements.

6. The heating system of claim 1, wherein the high-frequency power supply includes a direct current (DC) voltage regulator, a power device, and a transformer;
the DC voltage regulator is configured to receive a signal to be regulated and output a target regulated signal to the power device, the power device is configured to adjust a power of the target regulated signal to produce an electrical signal at a target alternating current (AC) frequency, and the transformer is configured to adjust a voltage of the electrical signal at the target AC frequency to enable the high-frequency power supply to provide the output signal.

7. The heating system of claim 6, wherein the DC voltage regulator includes a plurality of DC voltage regulator modules connected in parallel, an input terminal of each of the plurality of DC voltage regulator modules receives the signal to be regulated, respectively, and there is a time delay between the signals to be regulated received by different DC voltage regulator modules, and an output terminal of the plurality of DC voltage regulator modules connected in parallel outputs the target regulated signal, the target regulated signal is a superposition of regulated signals output by each of the plurality of DC voltage regulator modules.

8. The heating system of claim 7, wherein the DC voltage regulator module includes a Buck circuit and an LLC circuit, an input terminal of the Buck circuit receives the signal to be regulated, an output terminal of the Buck circuit is connected to an input terminal of the LLC circuit, and an output terminal of the LLC circuit outputs a signal that has been regulated by the Buck circuit and the LLC circuit.

9. The heating system of claim 7, wherein each of the plurality of DC voltage regulator modules includes a first regulator circuit and a second regulator circuit, the first regulator circuit and the second regulator circuit are connected in series, and the first regulator circuit and the second voltage regulator circuit have different efficiencies, an efficiency of the second voltage regulator circuit is greater than an efficiency of the first voltage regulator circuit, a stability of the first voltage regulator circuit is greater than a stability of the second voltage regulator circuit.

10. The heating system of claim 7, wherein a time delay between signals to be regulated received by two adjacent DC voltage regulator modules is related to a signal at an output terminal of at least one DC voltage regulator module.

11. The heating system of claim 10, wherein a ratio of a period of a signal at the output terminal of the DC voltage regulator module to a count of the plurality of DC voltage regulator modules is correlated with the time delay.

12. The heating system of claim 11, wherein a magnitude of the time delay is the same as the ratio of the period of the signal at the output terminal of the DC voltage regulator module to the count of the plurality of DC voltage regulator modules.

13. The heating system of claim 6, wherein the power device includes:
multi-level power modules, and a power module at each level is configured to generate an electrical signal at a preset AC frequency;
a controller configured to control an operation state of one or more of power modules among the multi-level power modules; and
an output terminal, coupled to the power module at each level among the multi-level power modules, respectively, and configured to generate an electrical signal at the target AC frequency according to an operation state of the multi-level power modules, and there is a corresponding relationship between the target AC frequency and a preset AC frequency of the power module at each level.

14. The heating system of claim 13, wherein a power of an electrical signal generated at the output terminal is the same as a sum of powers output by the multi-level power modules.

15. The heating system of claim 13, wherein the controller controls the multi-level power modules to be in operation states during different periods, respectively, and a sum of the preset AC frequency of the power module at each level is the same as the target AC frequency.

16. The heating system of claim 15, wherein in a same period, there are at least one power module in the operation state and at least one power module in a non-operation state;
the power device is further configured to adjust the target AC frequency of the electrical signal when a ratio of a reactive power of the high-frequency power supply to an output power of the high-frequency power supply exceeds a preset threshold value.

17. The heating system of claim 6, wherein the transformer includes:
a multi-layer printed circuit board (PCB), wherein each layer of the PCB includes a hollow structure;
a multi-layer planar coil, wherein each layer of the planar coil is fixed to one layer of the PCB and disposed around the hollow structure; and
a magnetic core structure, wherein the magnetic core structure includes a plurality of magnetic core plates, each of the plurality of magnetic core plates is disposed within the hollow structure of one layer of the PCB, and there is a spacing between two adjacent magnetic core plates.

18. The heating system of claim 17, wherein a thickness of each layer of the PCB is not more than 0.4 mm and a thickness of each layer of the planar coil is not more than 17 μm.

19. The heating system of claim 17, wherein the PCB is provided with one or more pads, and each of the one or more pads is configured to separate two adjacent layers of the PCB.

20. The heating system of claim 6, wherein the high-frequency power supply further includes a rectifier circuit, the rectifier circuit is connected to the DC voltage regulator, and the rectifier circuit is configured to rectify an external power supply and output a signal to be regulated.
